(19) United States
(12) Patent Application Publication
(10) Pub. No.: US 2016/0266181 A1
(43) Pub. Date: Sep. 15, 2016

(54) ELECTRIC POWER DEMAND PREDICTION SYSTEM, ELECTRIC POWER DEMAND PREDICTION METHOD, CONSUMER PROFILING SYSTEM, AND CONSUMER PROFILING METHOD

(71) Applicant: Kabushiki Kaisha Toshiba, Minato-ku (JP)

(72) Inventors: Takahiro KAWAGUCHI, Fuchu (JP); Shinya UMENO, Kawasaki (JP); Ryusei SHINGAKI, Ota (JP)

(73) Assignee: Kabushiki Kaisha Toshiba, Minato-ku (JP)

(21) Appl. No.: 15/158,729

(22) Filed: May 19, 2016

Related U.S. Application Data
(63) Continuation of application No. PCT/JP2013/081322, filed on Nov. 20, 2013.

(51) Int. Cl. G01R 21/133; H02J 3/00

(52) U.S. Cl. CPC G01R 21/133; H02J 3/00; H02J 2003/003

(57) ABSTRACT

An electric power demand prediction system has an extractor to select electric power consumption value data included in a certain period out of a consumer's past electric power consumption value data and to extract an outdoor temperature-electric power relation that is a relation between an outdoor temperature and outdoor-temperature-depend electric power varying in accordance with the outdoor temperature out of electric power consumption, a model generator to generate an electric power consumption prediction model which predicts electric power consumption by the consumer in accordance with the outdoor temperature based on the outdoor temperature-electric power relation extracted by the extractor, and a predictor to predict electric power consumption by the consumer at a time subject to prediction based on the electric power consumption prediction model generated by the model generator and the outdoor temperature at the time subject to prediction.

### CROSS-REFERENCE TO RELATED APPLICATIONS

This application is based upon and claims the benefit of priority from the prior PCT Application No. PCT/JP2013/081322, filed on Nov. 20, 2013, the entire contents of which are incorporated herein by reference.

### FIELD

Embodiments according to the present invention relate to an electric power demand prediction system, an electric power demand prediction method, a consumer profiling system, and a consumer profiling method.

### BACKGROUND

Smart grid has been studied recently as a next-generation energy supply system. In smart grid, it is assumed that demand and supply balance of electric power is maintained by issuing demand response or providing information to promote saving of electric power to consumers. In order to realize such a technology, it is necessary to predict excess and deficiency of electric power demand against electric power supply. Therefore, prediction of electric power demand, that is, prediction of electric power consumption by consumers is important.

Electric power consumption by consumers largely varies according to the outdoor temperature. This is because electric power consumption of air-conditioning equipment such as cooling and heating equipment increases in the summer season or winter season. Therefore, it is important to consider variation in electric power consumption according to the outdoor temperature in order to predict electric power consumption. As a technique to predict electric power consumption in consideration of the outdoor temperature, a method for comparing past data of the outdoor temperature with electric power consumption to calculate a correlation between the outdoor temperature and electric power consumption has been proposed.

However, in such a known technique, it has been difficult to predict electric power consumption with high accuracy because electric power consumption by consumers includes both electric power consumption that varies according to the outdoor temperature (hereinafter referred to as “outdoor-temperature-depend electric power”) and electric power consumption that varies irrespective of the outdoor temperature (for example, electric power consumption of lighting equipment). Since it is unclear as to how much outdoor-temperature-depend electric power is included in electric power consumption by simply comparing electric power consumption with the outdoor temperature, it is difficult to obtain a high correlation between electric power consumption and the outdoor temperature.

### BRIEF DESCRIPTION OF THE DRAWINGS

FIG. 1 is a block diagram showing a functional structure of an electric power demand prediction system according to the first embodiment;

FIG. 2 shows an example of electric power consumption value data;

FIG. 3 shows an example of outdoor temperature data;

FIG. 4 shows an example of predicted outdoor temperature data;

FIG. 5 is a block diagram showing a functional structure of a relation extractor;

FIG. 6 shows an example of base electric power and base electric power margin;

FIG. 7 shows an example of integrated outdoor temperature data and electric power consumption value data;

FIG. 8 shows an example of integrated outdoor temperature data and electric power consumption value data;

FIG. 9 shows an example of time period designation data;

FIG. 10 shows an example of selected electric power consumption value data;

FIG. 11 is a scattering diagram showing an example of selected electric power consumption value data;

FIG. 12 shows an example of selected electric power consumption value data;

FIG. 13 shows an example of electric power consumption value data with base electric power subtracted;

FIG. 14 shows an example of a related parameter;

FIG. 15 is a block diagram showing a functional structure of a model generator;

FIG. 16 schematically shows an example of a behavioral state estimation model;

FIG. 17 shows an example of a behavioral state estimation model in a tabular form;

FIG. 18 shows an example of a behavioral state estimated based on a behavioral state estimation model;

FIG. 19 shows an example of aggregated area numbers;

FIG. 20 shows an example of a behavioral state prediction model;

FIG. 21 shows an example of outdoor-temperature-depend electric power data;

FIG. 22 shows an example of behavioral electric power data;

FIG. 23 shows an example of a behavioral electric power prediction model;

FIG. 24 is a block diagram showing a functional structure of an electric power consumption predictor;

FIG. 25 shows electric power consumption and other data predicted by the electric power consumption predictor;

FIG. 26 is a flow chart showing an operation of an electric power demand prediction system according to an embodiment of the present invention;

FIG. 27 shows an example of an output display of the electric power demand prediction system according to an embodiment of the present invention;

FIG. 28 is a flow chart showing a relation extraction process;

FIG. 29 is a flow chart showing an electric power consumption prediction model generation process;

FIG. 30 is a flow chart showing an electric power consumption prediction process;

FIG. 31 is a block diagram showing a functional structure of an electric power demand prediction system according to a second embodiment;

FIG. 32 shows an example of preprocessed electric power consumption value data;

FIG. 33 is a flow chart showing an operation of the electric power demand prediction system according to the second embodiment;

FIG. 34 shows an example of preprocessed electric power consumption value data;

FIG. 35 is a scattering diagram showing an example of electric power consumption value data;

FIG. 36 is a block diagram showing a functional structure of an electric power demand prediction system according to a fourth embodiment;

FIG. 37 shows an example of ON/OFF information;

FIG. 38 shows an example of electric power consumption value data with base electric power subtracted;

FIG. 39 is a block diagram showing a functional structure of an electric power demand prediction system according to a fifth embodiment;

FIG. 40 shows an example of air-conditioning electric power data;

FIG. 41 is a block diagram showing a functional structure of an electric power demand prediction system according to a sixth embodiment;

FIG. 42 shows an example of an output display of an electric power demand prediction system according to an embodiment of the present invention; and

FIG. 43 is a block diagram showing a functional structure of a consumer profiling system.

### DETAILED DESCRIPTION

According to one embodiment, an electric power demand prediction system has:

an extractor to select electric power consumption value data included in a certain period out of a consumer's past electric power consumption value data and to extract an outdoor temperature-electric power relation that is a relation between an outdoor temperature and outdoor-temperature-depend electric power varying in accordance with the outdoor temperature out of electric power consumption based on the selected electric power consumption value data;

a model generator to generate an electric power consumption prediction model which predicts electric power consumption by the consumer in accordance with the outdoor temperature based on the outdoor temperature-electric power relation extracted by the extractor; and

a predictor to predict electric power consumption by the consumer at a time subject to prediction based on the electric power consumption prediction model generated by the model generator and the outdoor temperature at the time subject to prediction.

### (Electric Power Demand Prediction System)

Embodiments of an electric power demand prediction system will be described below with reference to the drawings. Although a case in which an electric power demand prediction system predicts electric power consumption by a consumer in the winter season will be described below, the electric power demand prediction system can predict electric power consumption by a consumer in the summer season or other seasons. In addition, a consumer for which the electric power demand prediction system predicts electric power consumption is a consumer that consumes outdoor-temperature-depend electric power and electric power according to actions by a user of the consumer (for example, resident), and may be a residential house, a shop, a multiunit residence (for example, condominium building), and the like. In the following description, a consumer is assumed to be a residential house.

### First Embodiment

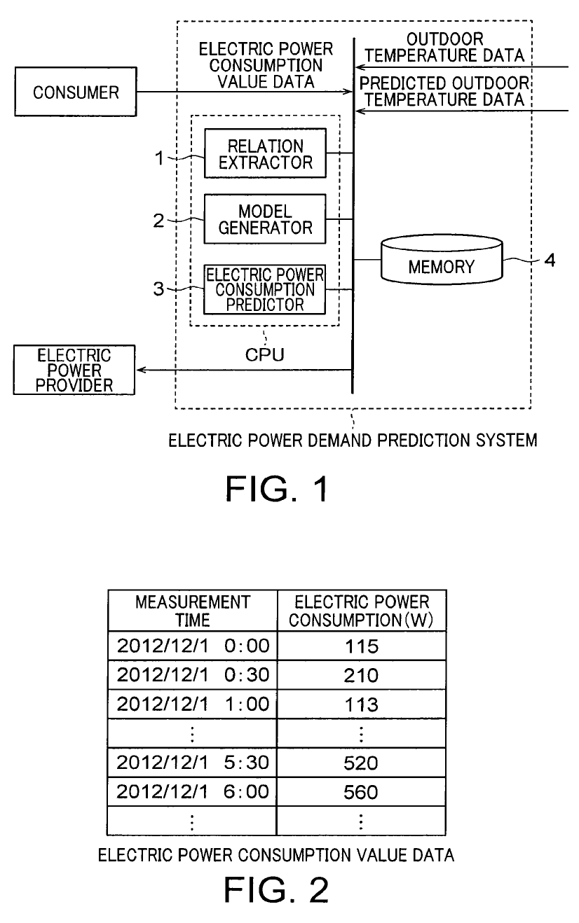

An electric power demand prediction system according to a first embodiment will be described below with reference to FIGS. 1 to 30. An electric power demand prediction system according to the present embodiment generates an electric power consumption prediction model based on a consumer's past electric power consumption value data and outdoor temperature data, and predicts electric power consumption by the consumer at the time subject to prediction based on the generated electric power consumption prediction model and outdoor temperature data at the time subject to prediction (time in future subject to prediction). The predicted electric power consumption is transmitted to an electric power provider (for example, electric power company, electric power retailer, and demand response provider) and used to control electric power supply and demand such as demand response (request to consumers to reduce electric power consumption), for example. FIG. 1 is a block diagram showing a functional structure of an electric power demand prediction system according to the present embodiment. As shown in FIG. 1, an electric power demand prediction system according to the present embodiment acquires electric power consumption value data from a consumer and acquires outdoor temperature data and predicted outdoor temperature data from outside the system.

The electric power consumption value data is data showing electric power consumption and electric power consumption amount by a consumer measured at the predetermined time by an electric power consumption measurement device (for example, smart meter) owned by the consumer or data showing these mean value or integrated value. Therefore, when all of electric power consumption by the consumer is measured by the electric power consumption measurement device, the electric power consumption value data is data showing overall electric power consumption by the consumer at the predetermined time. In contrast, when part of electric power consumption by the consumer is measured by the electric power consumption measurement device, the electric power consumption value data is data showing part of electric power consumption by the consumer at the predetermined time. Since an electric power consumption measurement device generally measures overall electric power consumption by a consumer, the electric power consumption value data is data showing overall electric power consumption by a consumer. The electric power consumption value data is transmitted to an electric power demand prediction system via the electric power consumption measurement device with or without wire. The transmitted electric power consumption value data is sorted in chronological order and stored in a memory 4 described later as history data. The memory 4 may store the transmitted electric power consumption value data or part of the transmitted electric power consumption value data. For example, when electric power consumption value data is transmitted by a consumer every one minute, the memory 4 may store only the electric power consumption value data in every five minutes or a mean value of electric power consumption in every one minute for five minutes every in every five minutes. FIG. 2 shows an example of electric power consumption value data stored in the memory 4. Although the electric power consumption value data of FIG. 2 is stored in every thirty minutes, the interval may be arbitrarily selected.

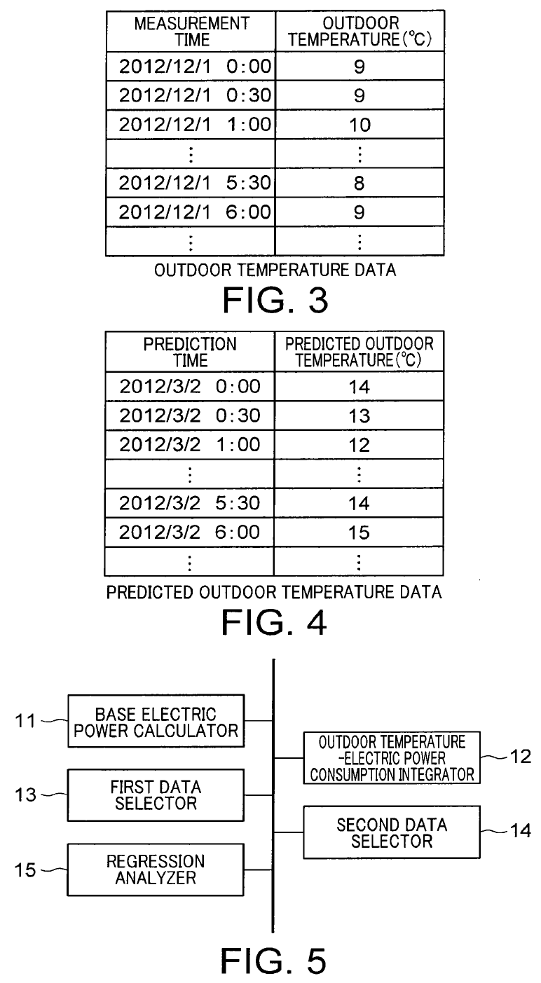

The outdoor temperature data is data showing the outdoor temperature at an area where a consumer exists measured at a predetermined time. The outdoor temperature data is transmitted to an electric power demand prediction system with or without wire from an outdoor temperature database provided outside the electric power demand prediction system or an external service that provides outdoor temperature data. The transmitted outdoor temperature data is sorted in chronological order and stored in the memory 4 as history data. The memory 4 may store all of the transmitted outdoor temperature data or only part of the transmitted outdoor temperature data. For example, when outdoor temperature data is transmitted from outside in every one minute, the memory 4 may only store the outdoor temperature data in every five minutes. FIG. 3 shows an example of outdoor temperature data stored in the memory 4. Although the outdoor temperature data is stored in every thirty minutes in FIG. 3, the interval may be arbitrarily selected. It is preferable that the memory 4 stores electric power consumption value data and outdoor temperature data that are measured at the same time. Accordingly, a damage of data to be used to predict electric power consumption by a consumer is prevented and prediction accuracy can be improved.

The predicted outdoor temperature data is data showing a prediction value of the outdoor temperature at the time subject to prediction at an area where a consumer exists. The predicted outdoor temperature data is transmitted to the electric power demand prediction system with or without wire from a predicted outdoor temperature database provided outside the electric power demand prediction system or an external service (such as weather forecast service) that provides predicted outdoor temperature data. The transmitted predicted outdoor temperature data is sorted in chronological order and stored in the memory 4. The memory 4 may store all of the transmitted predicted outdoor temperature data or only part of the transmitted predicted outdoor temperature data. For example, when the predicted outdoor temperature data is transmitted from outside in every one minute, the memory 4 may only store the predicted outdoor temperature data in every five minutes. FIG. 4 shows an example of the predicted outdoor temperature data stored in the memory 4. Although the predicted outdoor temperature data is stored in every thirty minutes in FIG. 4, the interval may be arbitrarily selected.

Next, a functional structure of the electric power demand prediction system will be described. As shown in FIG. 1, the electric power demand prediction system according to the present embodiment includes a relation extractor 1 (extraction means) for extracting a relation between the outdoor temperature and outdoor-temperature-depend electric power, a model generator 2 (model generation means) for generating a model for predicting electric power consumption based on the relation between the outdoor temperature and the outdoor-temperature-depend electric power extracted by the relation extractor 1, an electric power consumption predictor 3 (prediction means) for predicting electric power consumption by a consumer at the time subject to prediction based on the prediction model of electric power consumption generated by the model generator 2, and the memory 4 for storing various information. As described above, the memory 4 stores electric power consumption value data, outdoor temperature data, and predicted outdoor temperature data. The memory 4 also stores various information used or generated in the electric power consumption prediction process by the electric power demand prediction system. The electric power demand prediction system with the above structure can be realized with a computer device including a CPU or a memory as basic hardware. In more detail, functions of the relation extractor 1, the model generator 2, and the electric power consumption predictor 3 can be realized by executing a control program by a CPU. Also, a memory device such as non-volatile memory and external memory device can be used as the memory 4.

### (Relation Extractor)

First, the relation extractor 1 will be described. The relation extractor 1 acquires electric power consumption value data in a predetermined period (for example, arbitrary period of thirty days or sixty days) from the memory 4, and selects electric power consumption value data with a high correlation between the outdoor temperature and electric power consumption included in a certain period out of the acquired consumer's past electric power consumption value data. The relation extractor 1 extracts an outdoor temperature-electric power relation that is a relation between the outdoor temperature and outdoor-temperature-depend electric power (hereinafter referred to as “outdoor temperature-electric power relation”) based on the selected electric power consumption value data. Outdoor-temperature-depend electric power is electric power consumption that varies in accordance with the outdoor temperature out of electric power consumption by the consumer. The outdoor-temperature-depend electric power includes electric power consumption of air-conditioning equipment such as cooling and heating equipment, a floor heating device, an electric heater, and an electric fan, for example. Since the relation extractor 1 selects electric power consumption value data with high a correlation between the outdoor temperature and electric power consumption in advance, and extracts an outdoor temperature-electric power relation based on the selected electric power consumption value data, an outdoor temperature-electric power relation can be extracted with high accuracy. FIG. 5 is a block diagram showing a functional structure of the relation extractor 1. As shown in FIG. 5, the relation extractor 1 includes a base electric power calculator 11 (base electric power calculation means) for calculating base electric power, an outdoor temperature-electric power consumption integrator 12 for integrating outdoor temperature data and electric power consumption value data, a first data selector 13 (first data selection means) and a second data selector 14 (second data selection means) for selecting electric power consumption value data with a high correlation between the outdoor temperature and electric power consumption, and a regression analyzer 15 (analysis means) for performing a regression analysis based on the selected electric power consumption value data.

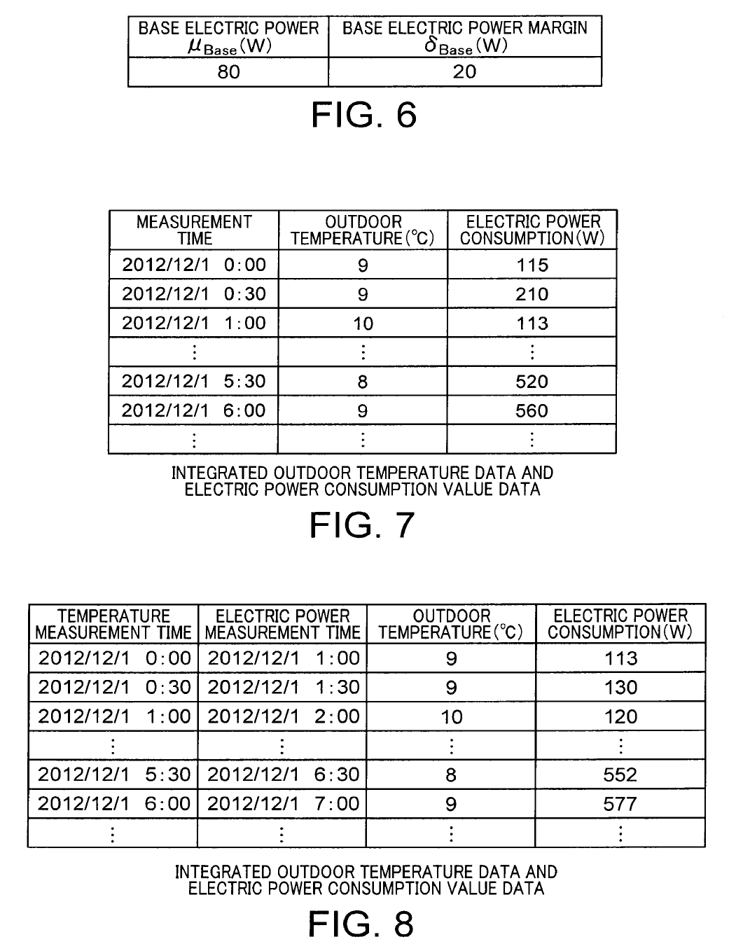

The base electric power calculator 11 calculates base electric power μ_{Base} based on the electric power consumption value data in a predetermined period acquired from the memory 4. The base electric power μ_{Base} is electric power serving as a reference of electric power consumption by a consumer, and calculated based on the assumption that it is constant in the predetermined period descried above. The base electric power μ_{Base} includes electric power consumption by electric equipment that always works independently from actions of a resident of a consumer such as standby electric power of electric equipment owned by the consumer. A method for calculating the base electric power μ_{Base} can be arbitrarily selected. For example, the base electric power μ_{Base} can be calculated by taking the statistic of the electric power consumption value data in the predetermined period. Specifically, frequency of electric power consumption in a predetermined period may be aggregated at a predetermined electric power interval (for example, 1 W interval), to calculate an electric power value as a mode value as the base electric power μ_{Base}. At this time, the minimum electric power value more than the base electric power μ_{Base} with frequency of the minimum value may be calculated as threshold electric power μₜₕ. The threshold electric power μₜₕ can be used as a parameter for selecting data in the second data selector 14 described later. A difference between the threshold electric power μₜₕ and the base electric power μ_{Base} may be calculated as a base electric power margin δ_{Base} (=μₜₕ−μ_{Base}) instead of the threshold electric power μₜₕ. These parameters calculated by the base electric power calculator 11 (base electric power δ_{Base}) threshold electric power μₜₕ, and base electric power margin δ_{Base}) are stored in the memory 4. FIG. 6 shows an example of the base electric power μ_{Base} and the base electric power margin δ_{Base} calculated based the electric power consumption value data of FIG. 2.

The outdoor temperature-electric power consumption integrator 12 acquires outdoor temperature data in a predetermined period (for example, arbitrary period of thirty days or sixty days) from the memory 4, and couples the acquired outdoor temperature data and the electric power consumption value data described above. The outdoor temperature data and the electric power consumption value data are integrated to each other based on the time of both data. The outdoor temperature-electric power consumption integrator 12 may couple the electric power consumption value data and the outdoor temperature data with the same time or couple the electric power consumption value data and the outdoor temperature data with a predetermined different time. The integrated outdoor temperature data and electric power consumption value data are stored in the memory 4. FIGS. 7 and 8 show an example of the integrated electric power consumption history data of FIG. 2 and outdoor temperature history data of FIG. 3. In FIG. 7, the outdoor temperature data and the electric power consumption value data with the same time are integrated, and in FIG. 8, the outdoor temperature data and the electric power consumption value data with one-hour shift are integrated.

As shown in FIG. 8, time lag until the outdoor temperature influences the room temperature can be considered by shifting the outdoor temperature data and the electric power consumption value data to be integrated by a predetermined time. For example, when the outdoor temperature decreases (increases), the room temperature decreases (increases) due to decrease (increase) of the outdoor temperature, a resident of a consumer feels cold (hot) and uses heating equipment (cooling equipment), and the amount of consumption of outdoor-temperature-depend electric power changes. At this time, if time lag occurs between change in the outdoor temperature and change in the room temperature, time lag sometimes occurs between change in the outdoor temperature and change in the outdoor-temperature-depend electric power. In this case, even if data with the same time are integrated, there is a possibility that an outdoor temperature-electric power relation cannot be accurately extracted. Then, it is possible to more accurately extract an outdoor temperature-electric power relation by integrating the outdoor temperature data and the electric power consumption value data that are shifted from each other for a predetermined time in consideration of such time lag. Since the change in the outdoor temperature generally occurs first in the time lag described above, it is preferable that the outdoor temperature-electric power consumption integrator 12 couples the outdoor temperature data and the electric power consumption value data after a predetermined time (for example, one to two hours) from the outdoor temperature data. In addition, since the time lag changes in accordance with heat insulating properties and ventilation properties of a building of a consumer, a time to shift the data to be integrated may be different for each consumer.

The first data selector 13 selects electric power consumption value data with a high correlation between the outdoor temperature and electric power consumption from the electric power consumption value data stored in the memory 4. The electric power consumption value data with a high correlation between the outdoor temperature and electric power consumption is electric power consumption value data with less behavioral electric power included in electric power consumption. The behavioral electric power is residual electric power consumption obtained by removing base electric power and outdoor-temperature-depend electric power from electric power consumption by a consumer. As the behavioral electric power, electric power consumption that varies in accordance with actions of a resident of a consumer (for example, electric power consumption of an illuminating device or a television) is assumed. That is, electric power consumption by a consumer includes base electric power that is constant for a predetermined period, outdoor-temperature-depend electric power that varies in accordance with the outdoor temperature, and behavioral electric power that varies in accordance with actions of a resident of a consumer. Since the base electric power is constant for the predetermined period, if the behavioral electric power included in electric power consumption is little, the correlation between the outdoor temperature and electric power consumption becomes high.

The first data selector 13 selects electric power consumption value data included in a predetermined time range as electric power consumption value data with a high correlation between the outdoor temperature and electric power consumption. Since the behavioral electric power is considered to be electric power consumption that varies in accordance with actions of a resident of a consumer, electric power consumption value data in a time period when, for example, the resident is asleep or is absent from home is assumed to include less behavioral electric power included in electric power consumption. Therefore, the first data selector 13 can select electric power consumption value data in a time period when a resident of a consumer is asleep or absent from home as electric power consumption value data with a high correlation between the outdoor temperature and electric power consumption. When a time period in which a resident is asleep or absent from home is known in advance, the first data selector 13 is only required to select the electric power consumption value data in that time period. In addition, it is generally assumed that a resident is asleep at night, and the first data selector 13 may select electric power consumption value data at night. The time period of the electric power consumption value data selected by the first data selector 13 may be stored in the memory 4 in advance as time period designation data. Moreover, the first data selector 13 may select electric power consumption value data in the time period when a resident is absent from home by identifying that time period based on position information of the resident or the like received from a terminal such as smartphone carried by the resident, for example.

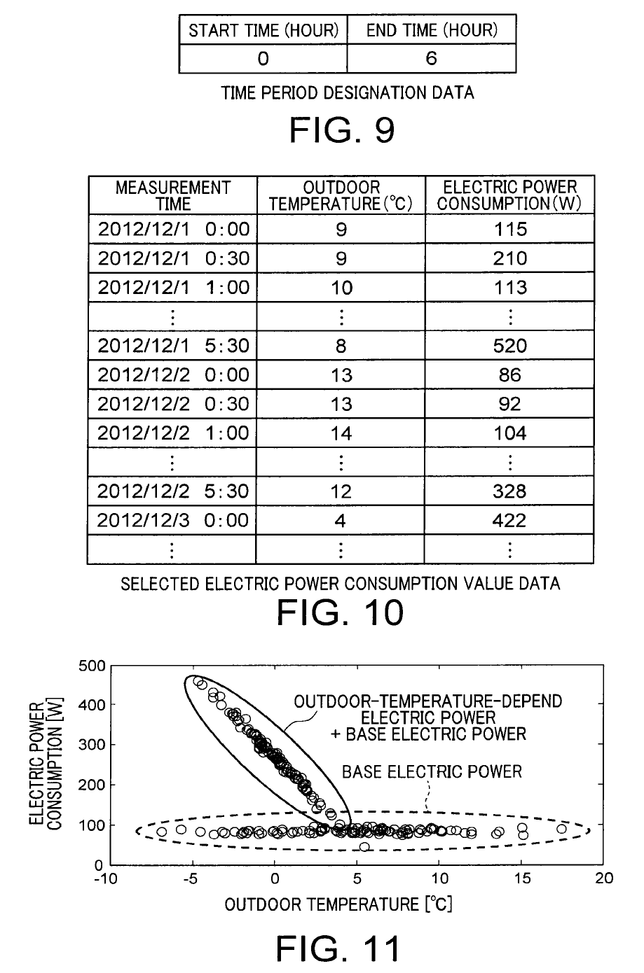

FIG. 9 shows an example of time period designation data. In the time period designation data in FIGS. 9, 0:00 to 6:00 is designated as a night time period in which a resident is asleep. The time period designated by the time period designation data is not limited thereto. The first data selector 13 acquires the time period designation data from the memory 4, and selects electric power consumption value data based on the time period designation data. FIG. 10 shows an example of the electric power consumption value data selected by the first data selector 13. The electric power consumption value data in FIG. 10 is electric power consumption value data selected from the electric power consumption value data of FIG. 8 by the first data selector 13 based on the time period designation data of FIG. 9. The electric power consumption value data selected by the first data selector 13 is stored in the memory 4.

The first data selector 13 may select electric power consumption value data from the electric power consumption value data in the predetermined period before the outdoor temperature data and the electric power consumption value data are integrated by the outdoor temperature-electric power consumption integrator 12. In this case, the outdoor temperature-electric power consumption integrator 12 couples the electric power consumption value data selected by the first data selector 13 and the outdoor temperature data stored in the memory 4. In addition, as shown in FIG. 8, when the times of the outdoor temperature data and the electric power consumption value data to be integrated are shifted from each other, the time period designation data may designate a time period in which electric power consumption is selected by one of the time period of the outdoor temperature data and the time period of the electric power consumption value data.

FIG. 11 is a scattering diagram in which the electric power consumption value data selected by the first data selector 13 is plotted on an outdoor temperature-electric power consumption plane. In FIG. 11, the horizontal axis represents the outdoor temperature (° C.) and the vertical axis represents electric power consumption (W). Each dot plotted on the plane represents the electric power consumption value data integrated to the outdoor temperature data. As shown in FIG. 11, the electric power consumption value data selected by the first data selector 13 includes electric power consumption value data in which electric power consumption is not dependent on the outdoor temperature and substantially constant (electric power consumption value data surrounded by a broken line in FIG. 11) and electric power consumption value data in which electric power consumption correlates with the outdoor temperature (electric power consumption value data surrounded by a solid line in FIG. 11). In the electric power consumption value data in which electric power consumption is substantially constant, most of electric power consumption is base electric power, and only little outdoor-temperature-depend electric power and behavioral electric power are included in electric power consumption. In addition, in the electric power consumption value data in which electric power consumption varies in accordance with the outdoor temperature, most of electric power consumption is base electric power and outdoor-temperature-depend electric power, and only little behavioral electric power is included in electric power consumption. By selecting electric power consumption value data in a predetermined time period by the first data selector in this manner, it is possible to select data in which only little behavioral electric power is included in electric power consumption, that is, electric power consumption value data with a high correlation between the outdoor temperature and electric power consumption. Since FIG. 11 shows electric power consumption value data in the winter season, outdoor-temperature-depend electric power increases in accordance with decrease of the outdoor temperature. This is because frequency of use of a heating apparatus or the like increases as the outdoor temperature decreases. In contrast, since frequency of use of a cooling apparatus or the like increases as the outdoor temperature increases in electric power consumption value data in the summer season, outdoor-temperature-depend electric power increases in accordance with increase of the outdoor temperature.

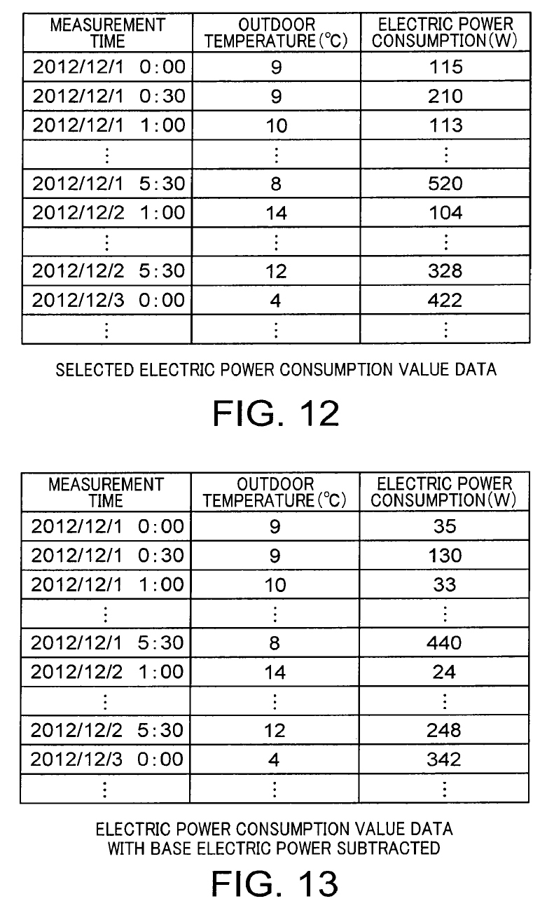

The second data selector 14 selects electric power consumption value data with larger electric power consumption than the base electric power μ_{Base} calculated by the base electric power calculator 11 from the electric power consumption value data selected by the first data selector 13. That is, the electric power consumption value data surrounded by the solid line in FIG. 11 is selected and the electric power consumption value data surrounded by the broken line is removed. Accordingly, it is possible to remove data in which most of electric power consumption is base electric power from the data selected by the first data selector 13 and select electric power consumption value data in which most of electric power consumption is outdoor-temperature-depend electric power and base electric power, that is, data with a high correlation between the outdoor temperature and electric power consumption. The second data selector 14 may select electric power consumption value data with electric power consumption larger than threshold electric power μₜₕ (=μ_{Base}+δ_{Base}) instead of selecting electric power consumption value data with electric power consumption larger than base electric power μ_{Base}. Accordingly, it is possible to remove electric power consumption value data with electric power consumption around base electric power and to prevent an effect of fluctuation of electric power consumption around base electric power. Therefore, it is possible to select data with a higher correlation between the outdoor temperature and electric power consumption. FIG. 12 shows an example of the electric power consumption value data selected by the second data selector 14. In FIG. 12, electric power consumption value data with electric power consumption larger than threshold electric power μₜₕ (=80 W+20 W) is selected based on the parameter of FIG. 6 out of the electric power consumption value data of FIG. 10.

The second data selector 14 may select electric power consumption value data with electric power consumption larger than base electric power out of the electric power consumption value data in the predetermined period before the first data selector 13 selects electric power consumption value data. In this case, the first data selector 13 selects electric power consumption value data in a predetermined time period out of the electric power consumption value data selected by the second data selector 14. In addition, the second data selector 14 may select electric power consumption value data before the outdoor temperature-electric power consumption integrator 12 couples outdoor temperature data and electric power consumption value data. In this case, the outdoor temperature-electric power consumption integrator 12 couples the electric power consumption value data selected by the second data selector 14 and the outdoor temperature data stored in the memory 4.

The regression analyzer 15 performs a regression analysis based on the electric power consumption value data selected by the second data selector 14 with the outdoor temperature being an explanatory variable and outdoor-temperature-depend electric power being an objective variable. In the selected electric power consumption value data, most of electric power consumption is base electric power and outdoor-temperature-depend electric power. Since the base electric power is constant, electric power consumption can be represented by a regression formula with the outdoor temperature being a parameter. The regression analyzer 15 can perform a regression analysis by any ways such as linear regression by a least-square method and non-linear regression with start of a polynomial. In addition, an effect of the base electric power may be removed from the electric power consumption value data by subtracting the base electric power from the electric power consumption before the regression analyzer 15 performs a regression analysis. FIG. 13 shows an example of electric power consumption value data with base electric power subtracted. The electric power consumption value data in FIG. 13 is made by subtracting the base electric power of FIG. 6 from the electric power consumption value data of FIG. 12. Since base electric power is subtracted in the electric power consumption value data of FIG. 13, most of electric power consumption is outdoor-temperature-depend electric power. Therefore, an outdoor temperature-electric power relation can be extracted with high accuracy by performing a regression analysis based on the electric power consumption value data.

An example of methods in which the regression analyzer 15 calculates related parameters will be described below. Related parameters are various parameters obtained by performing a regression analysis by the regression analyzer 15. An outdoor temperature-electric power relation is extracted by the regression analyzer 15 as a related parameter. A case in which the regression analyzer 15 calculates a related parameter by linear regression will be described below. When the regression analyzer 15 analyzes an outdoor temperature-electric power relation by linear regression, a regression formula is represented by the following primary formula.

y=ax+b [Formula 1]

Here, an objective variable y is outdoor-temperature-depend electric power (W), an explanatory variable x is the outdoor temperature (° C.), “a” is a slope of the regression formula, and “b” is an intercept. The “a” and “b” in the above regression formula are related parameters. For example, when the regression analyzer 15 performs a regression analysis by a least-square method, the related parameters “a” and “b” can be obtained by the following formulae.

$$a = \frac{n {\sum }_{k = 1}^{n} {x}_{k} {y}_{k} - {\sum }_{k = 1}^{n} {x}_{k} {\sum }_{k = 1}^{n} {y}_{k}}{n {\sum }_{k = 1}^{n} {x}_{k}^{2} - {( {\sum }_{k = 1}^{n} {x}_{k} )}^{2}} \\ b = \frac{{\sum }_{k = 1}^{n} {x}_{k}^{2} {\sum }_{k = 1}^{n} {y}_{k} - {\sum }_{k = 1}^{n} {x}_{k} {y}_{k} {\sum }_{k = 1}^{n} {x}_{k}}{n {\sum }_{k = 1}^{n} {x}_{k}^{2} - {( {\sum }_{k = 1}^{n} {x}_{k} )}^{2}} \qquad [ Formula 2 ]$$

In addition, the regression analyzer 15 may calculate a variation δ_{AC} of outdoor-temperature-depend electric power. For example, a variation δ_{AC} of outdoor-temperature-depend electric power can be calculated by the following formula with dispersion.

$${σ}_{A C}^{2} = \frac{1}{n} {\sum }_{k = 1}^{n} {( {y}_{k} - ( α {x}_{k} + b ) )}^{2} \\ {δ}_{A C} = 3 {σ}_{A C} \qquad [ Formula 3 ]$$

δ_{AC} can be multiple of any constant of σ_{AC}. Moreover, the variation δ_{AC} may be calculated as described above or set in advance. Furthermore, the regression analyzer 15 calculates the threshold temperature Tₜₕ at which use of outdoor-temperature-depend electric power is started. The threshold temperature Tₜₕ is the outdoor temperature where the regression line crosses base electric power. Therefore, when a regression analysis is performed based on electric power consumption value data from which base electric power is not subtracted, x that makes y=μ_{Base} is the threshold temperature Tₜₕ. On the other hand, when a regression analysis is performed based on electric power consumption value data with base electric power subtracted, x that makes y=0 is the threshold temperature Tₜₕ, and the threshold temperature Tₜₕ can be calculated as follows.

$${T}_{th} = - \frac{b}{a} \qquad [ Formula 4 ]$$

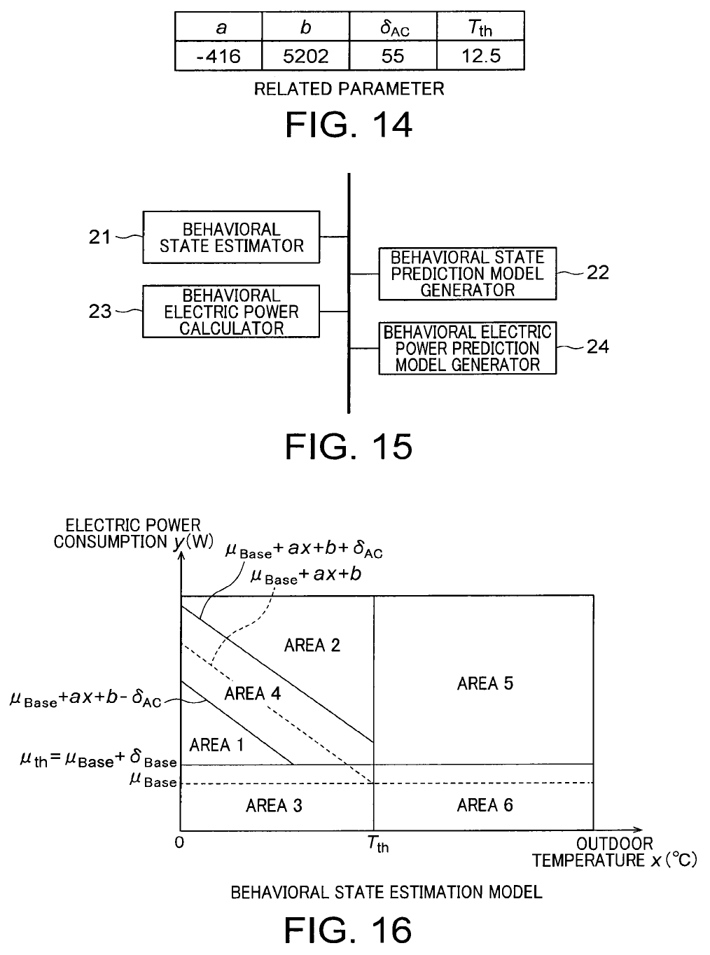

The “a”, “b”, δ_{AC}, and Tₜₕ calculated as described above are stored in the memory 4 as related parameters. FIG. 14 shows related parameters calculated based on the electric power consumption value data of FIG. 13. With the configuration descried above, the relation extractor 1 can extract outdoor temperature-electric power relation (related parameter) with high accuracy.

### (Model Generator)

Next, the model generator 2 will be described. The model generator 2 generates an electric power consumption prediction model for predicting electric power consumption by a consumer in accordance with the outdoor temperature based on the outdoor temperature-electric power relation (related parameter) extracted by the relation extractor 1. An electric power consumption prediction model includes a behavioral state prediction model for predicting a behavioral state of a consumer in accordance with the outdoor temperature and a behavioral electric power prediction model for predicting behavioral electric power in each behavioral state. FIG. 15 shows a functional structure of the model generator 2. As shown in FIG. 15, the model generator 2 includes a behavioral state estimator 21 (behavioral state estimation means) for estimating a consumer's past behavioral state, a behavioral state prediction model generator 22 (behavioral state prediction model generation means) for generating a behavioral state prediction model, a behavioral electric power calculator 23 (behavioral electric power calculation means) for calculating a consumer's past behavioral electric power, and a behavioral electric power prediction model generator 24 (behavioral electric power prediction model generation means) for predicting behavioral electric power in each behavioral state.

The behavioral state estimator 21 estimates a consumer's past behavioral state based on outdoor temperature-electric power relation (related parameter) and electric power consumption value data. A behavioral state is a state of use of electric power by a consumer and includes a state in which outdoor-temperature-depend electric power is being used, a state in which outdoor-temperature-depend electric power is not being used, a state in which behavioral electric power is being used, and a state behavioral electric power is not being used. The behavioral state estimator 21 generates a behavioral state estimation model based on a related parameter for estimating a consumer's behavioral state. FIG. 16 schematically shows an example of a behavioral state estimation model. FIG. 16 is an outdoor temperature-electric power consumption plane divided into several areas by related parameters, and the horizontal axis represents the outdoor temperature x (° C.) and the vertical axis represents electric power consumption y (W). In FIG. 16, each area surrounded by solid lines corresponds to a consumer's behavioral states. The behavioral state estimator 21 identifies an area including electric power consumption value data to estimate a consumer's behavioral state. For example, electric power consumption value data is included in the area 3 when the outdoor temperature of the integrated outdoor temperature data is lower than the threshold temperature Tₜₕ and electric power consumption is equal or less than base electric power μ_{Base}.

When the outdoor temperature of outdoor temperature data integrated to electric power consumption value data is xₖ, and electric power consumption of electric power consumption value data is yₖ, the area 1 is an area satisfying the following formula.

xₖ<Tₜₕ

μ_{Base}+δ_{Base}<yₖ≦μ_{Base}+axₖ+b−δ_{AC}

The area 1 is an area in which the outdoor temperature is lower than the threshold temperature Tₜₕ and electric power consumption is larger than the threshold electric power μₜₕ (=μ_{Base}+δ_{Base}) and an area lower than the area in which a regression line of outdoor-temperature-depend electric power is included. The behavioral state estimator 21 estimates that a behavioral state of electric power consumption value data included in the area 1 is a state in which behavioral electric power is being used and outdoor-temperature-depend electric power is not being used.

Similarly, the area 2 is an area satisfying the following formula.

xₖ<Tₜₕ

μ_{Base}+axₖ+b+δ_{AC}≦yₖ

The area 2 is an area in which the outdoor temperature is lower than the threshold temperature Tₜₕ and electric power consumption is higher than the area including a regression line of outdoor-temperature-depend electric power. The behavioral state estimator 21 estimates that a behavioral state of electric power consumption value data included in the area 2 is a state in which outdoor-temperature-depend electric power and behavioral electric power are being used.

The area 3 is an area satisfying the following formula.

xₖ<Tₜₕ

yₖ≦μ_{Base}+δ_{Base}

The area 3 is an area in which the outdoor temperature is lower than the threshold temperature Tₜₕ and electric power consumption is less than the threshold electric power Tₜₕ. The behavioral state estimator 21 estimates that a behavioral state of electric power consumption value data included in the area 3 is a state in which outdoor-temperature-depend electric power and behavioral electric power are not being used.

The area 4 is an area satisfying the following formula.

xₖ<Tₜₕ

μ_{Base}+axₖ+b−δ_{AC}<yₖ≦μ_{Base}+axₖ+b+δ_{AC}

μ_{Base}+δ_{Base}≦yₖ

The area 4 is an area in which the outdoor temperature is lower than the threshold temperature Tₜₕ and electric power consumption approaches a regression line of outdoor-temperature-depend electric power. The behavioral state estimator 21 estimates that a behavioral state of electric power consumption value data included in the area 4 is a state in which outdoor-temperature-depend electric power is being used and behavioral electric power is not being used.

The area 5 is an area satisfying the following formula.

Tₜₕ≦xₖ

μ_{Base}+δ_{Base}<yₖ

The area 5 is an area in which the outdoor temperature is higher than the threshold temperature Tₜₕ and electric power consumption is larger than the threshold electric power μₜₕ. The behavioral state estimator 21 estimates that a behavioral state of electric power consumption value data included in the area 5 is a state in which outdoor-temperature-depend electric power is not being used and behavioral electric power is being used.

The area 6 is an area satisfying the following formula.

Tₜₕ≦xₖ

yₖ≦μ_{Base}+δ_{Base}

The area 6 is an area in which the outdoor temperature is higher than the threshold temperature Tₜₕ and electric power consumption is less than the threshold electric power μₜₕ. The behavioral state estimator 21 estimates that a behavioral state of electric power consumption value data included in the area 6 is a state in which outdoor-temperature-depend electric power and behavioral electric power are not being used.

A method for dividing the area is not limited thereto. For example, μ_{Base} may be used instead of μ_{Base}+δ_{Base} in the method for dividing described above. In addition, the area may be divided by a parameter other than the outdoor temperature or electric power consumption. Moreover, when the consumer owns several equipment (such as air-conditioning equipment and floor heating) that use outdoor-temperature-depend electric power and operates different equipment according to the outdoor temperature, an outdoor temperature-electric power relation is not always linear. In such a case, the regression analyzer 15 may perform a regression analysis by non-linear regression and replace axₖ+b of the above regression formula with the obtained non-linear regression formula to divide the area

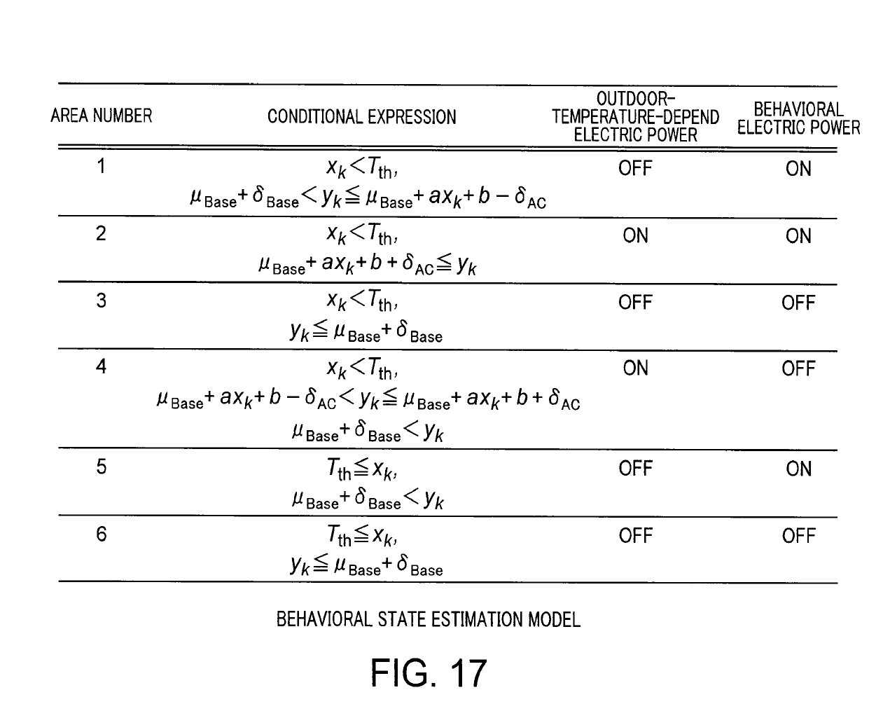

FIG. 17 shows the behavioral state estimation model described above in a tabular form. In FIG. 17, ON means that electric power is being used and OFF means that electric power is not being used. The behavioral state estimator 21 compares a behavioral state estimation model with electric power consumption value data, identifies the area number including the electric power consumption value data, and estimates that a behavioral state corresponding to the identified area number is a behavioral state of the consumer at the time when the electric power consumption value data is acquired. The estimated behavioral state (area number) is correlated with the electric power consumption value data and stored in the memory 4. The behavioral state thus estimated may be correlated with actions of the resident. For example, a state in which behavioral electric power is being used can be correlated with a state in which the resident is at home and a state in which behavioral electric power is not being used can be correlated with a state in which the resident is not present (absent from home). In addition, a state in which behavioral electric power is not being used at night (for example, 0:00 to 6:00) may be correlated with a state in which the resident is asleep. Actions of the resident correlated with behavioral states of the consumer are stored in the memory 4.

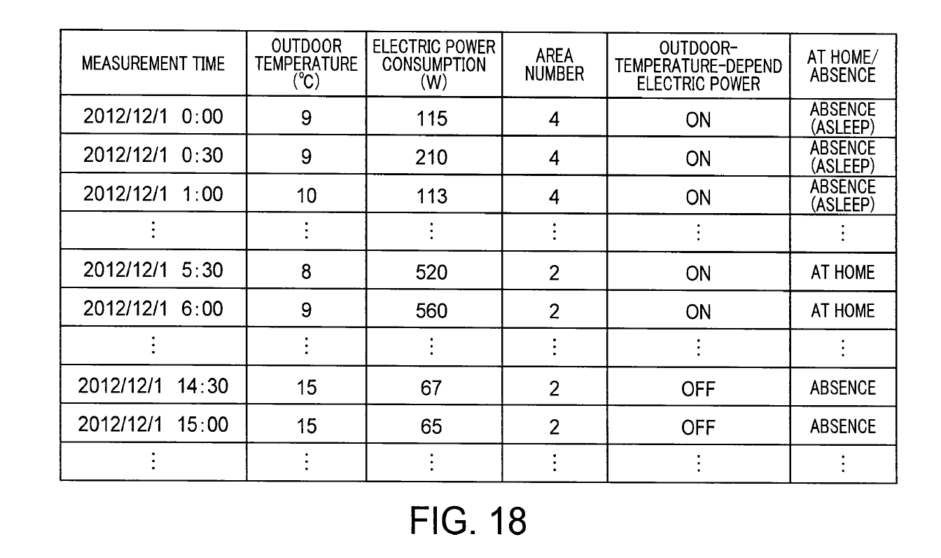

FIG. 18 shows behavioral states of the consumer estimated with respect to the electric power consumption value data of FIG. 7. In FIG. 18, use and non-use of behavioral electric power correspond to states in which the consumer is at home and not present, respectively. In addition, a state in which the consumer is not present corresponds to a state in which the consumer is asleep.

In order to estimate a behavioral state in the summer season, it is only required to switch Tₜₕ≦xₖ and xₖ<Tₜₕ in the behavioral state estimation model. In addition, both of the threshold temperature for the winter season and the threshold temperature for the summer season may be prepared. In this case, a state in which outdoor-temperature-depend electric power is being used is set in an area in which the outdoor temperature is lower than the threshold temperature in the winter season and in an area in which the outdoor temperature is equal to or higher than the threshold temperature in the summer season. Accordingly, it is possible to estimate a behavioral state of the consumer through the year with a single behavioral state estimation model.

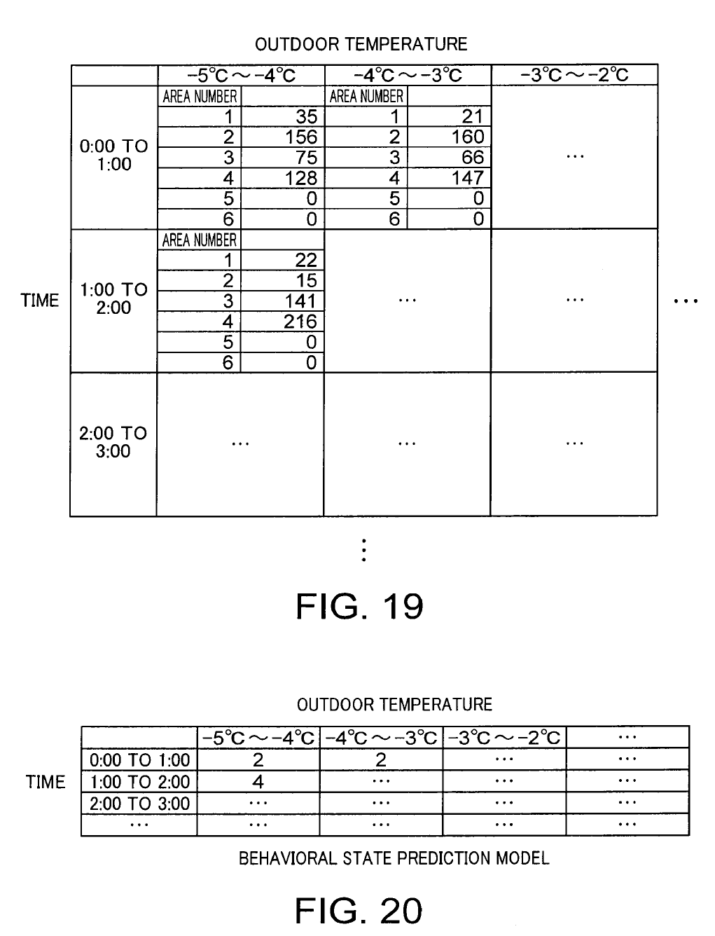

The behavioral state prediction model generator 22 takes the statistic of a consumer's past behavioral state estimated by the behavioral state estimator 21 to generate a behavioral state prediction model for predicting a behavioral state of the consumer in accordance with the outdoor temperature. For example, the behavioral state prediction model generator 22 aggregates area numbers of electric power consumption value data for each outdoor temperature and time. FIG. 19 shows an example of area numbers aggregated for each outdoor temperature and time. Although the outdoor temperature is aggregated for every one ° C. and the time is aggregated in every one hour in FIG. 19, the interval of the outdoor temperature and the time to aggregate area numbers is not limited thereto. Next, the behavioral state prediction model generator 22 selects, for example, the area number that is aggregated the most for each outdoor temperature and time out of the area numbers thus aggregated as an area number estimated for that outdoor temperature and time. For example, in FIG. 19, the area 2 is selected as an area number for 0:00 to 1:00 and −5° C. to −4° C.

In addition, the behavioral state prediction model generator 22 may learn a consumer's past behavioral state estimated by the behavioral state estimator 21 to generate a behavioral state prediction model. The behavioral state prediction model generator 22 can generate a behavioral state prediction model with an existing machine learning method such as polynomial logistic determination, neural network, and support vector machine with the time and the outdoor temperature being explanatory variables and a behavioral state being an objective variable.

The behavioral state prediction model 22 selects an area number for each outdoor temperature and time to generate a behavioral state prediction model. The generated behavioral state prediction model is stored in the memory 4. FIG. 20 shows an example of a behavioral state prediction model generated based on the aggregation result of FIG. 19. The electric power consumption predictor 3 that will be described later refers to the behavioral state prediction model stored in the memory 4 and predicts a behavioral state of the consumer at the time subject to prediction. As a parameter of a behavioral state prediction model, another parameter such as weather and day can be used in addition to outdoor temperature and time.

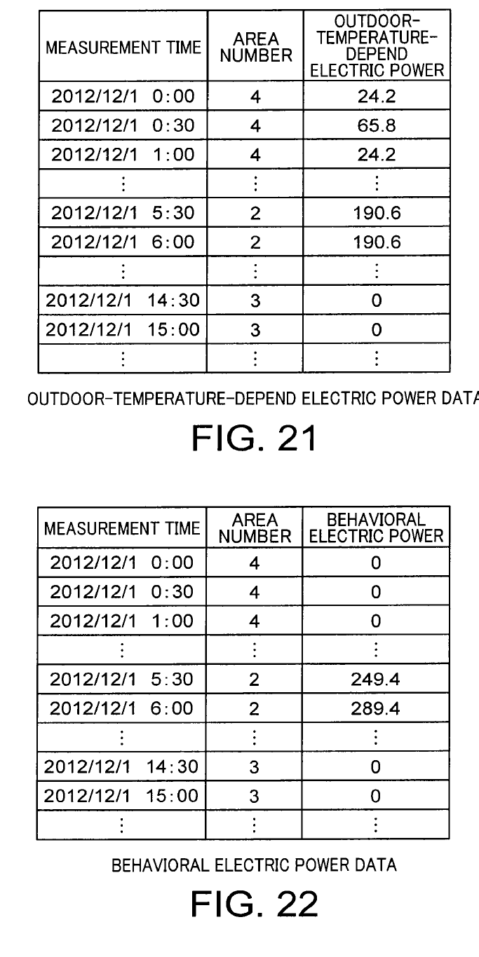

The behavioral electric power calculator 23 calculates outdoor-temperature-depend electric power y_{Ac} and behavioral electric power y_{act} in the consumer's past electric power consumption value data based on the electric power consumption value data and the behavioral state of the electric power consumption value data. First, the behavioral electric power calculator 23 calculates outdoor-temperature-depend electric power y_{AC} for each electric power consumption value data. As shown in FIG. 21, the behavioral electric power calculator 23 calculates outdoor-temperature-depend electric power y_{AC} of electric power consumption value data in a state in which outdoor-temperature-depend electric power is not being used, that is, in the areas 1, 3, 5, and 6 as follows.

y_{AC}=0 [Formula 5]

On the other hand, the behavioral electric power calculator 23 calculates outdoor-temperature-depend electric power y_{AC} of electric power consumption value data in a state in which outdoor-temperature-depend electric power is being used, that is, in the areas 2 and 4 as follows based on the related parameter stored in the memory 4.

y_{AC}=ax+b [Formula 6]

The outdoor-temperature-depend electric power thus calculated is stored in the memory 4 as outdoor-temperature-depend electric power data correlated with the time and the area number. FIG. 21 shows an example of outdoor-temperature-depend electric power data generated based on the electric power consumption value data and the behavioral state of FIG. 18.

Next, the behavioral electric power calculator 23 calculates behavioral electric power y_{act} for each electric power consumption value data. The behavioral electric power calculator 23 calculates behavioral electric power y_{act} of electric power consumption value data in a state in which behavioral electric power is not being used, that is, in the areas 3, 4, and 6 as follows.

y_{act}=0 [Formula 7]

On the other hand, the behavioral electric power calculator 23 calculates behavioral electric power y_{act} of electric power consumption value data in a state in which behavioral electric power is being used, that is, in the areas 1, 2, and 5 as follows based on the related parameter, the outdoor-temperature-depend electric power y_{AC}, and the electric power consumption y of the electric power consumption value data stored in the memory 4.

y_{act}=y−y_{AC}−μ_{Base} [Formula 8]

That is, the behavioral electric power calculator 23 subtracts the base electric power μ_{Base} and the outdoor-temperature-depend electric power y_{AC} from the electric power consumption y to calculate the behavioral electric power y_{act}. The behavioral electric power thus calculated is stored in the memory 4 as behavioral electric power data correlated with the time and the area number. FIG. 22 shows an example of behavioral electric power data generated based on the electric power consumption value data of FIG. 18 and the outdoor-temperature-depend electric power of FIG. 21.

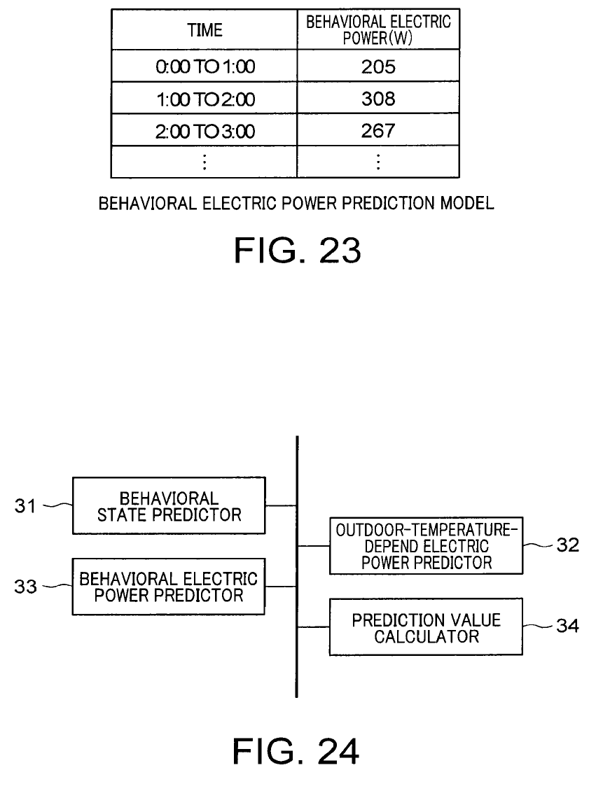

The behavioral electric power prediction model generator 24 generates a behavioral electric power prediction model for predicting a consumer's behavioral electric power in each behavioral state based on the behavioral electric power calculated by the behavioral electric power calculator 23 and the behavioral state estimated by the behavioral state estimation means. The behavioral electric power prediction model generator 24 refers to the behavioral electric power data generated by the behavioral electric power calculator 23 and takes the statistic of the behavioral electric power in a state in which behavioral electric power is being used (areas 1, 2, and 5) for each time to calculate a prediction value of behavioral electric power for each time. Statistic is carried out by taking a mean value or mode value of behavioral electric power for each time, for example. In addition, the time interval for calculating a prediction value of behavioral electric power can be arbitrarily set. Accordingly, a behavioral electric power prediction model is generated. FIG. 23 shows an example of a behavioral electric power prediction model. FIG. 23 shows a behavioral electric power prediction model generated by calculating a prediction value of behavioral electric power for each time in a state in which behavioral electric power is being used based on the behavioral electric power data of FIG. 22.

In addition, the behavioral electric power prediction model generator 24 may generate any regression model with the time being an explanatory variable and the behavioral electric power being an objective variable based on the behavioral electric power calculated by the behavioral electric power calculator 23 and the behavioral state estimated by the behavioral state estimation means. In order to generate a regression model, the behavioral electric power prediction model generator 24 can use existing methods such as regression by neural network and support vector regression. The explanatory variable may include the weather, the day, and the like.

In FIG. 23, a behavioral electric power prediction model is generated based on existence and non-existence of behavioral electric power; however, a behavioral electric power prediction model may be generated by taking the statistic of the behavioral electric power data of FIG. 22 for each area. In this case, the behavioral electric power prediction model generator 24 calculates a prediction value of behavioral electric power for each time in the areas of the state in which behavioral electric power is being used (areas 1, 2, and 5) to generate a behavioral electric power prediction model. In addition, a behavioral electric power prediction model may be generated with other parameters such as the temperature and the day instead of the time and the area. The generated behavioral electric power prediction model is stored in the memory 4. The electric power consumption predictor 3 described later refers to the behavioral electric power prediction model stored in the memory 4 to predict behavioral electric power of the consumer at the time subject to prediction.

### (Electric Power Consumption Predictor)

Next, the electric power consumption predictor 3 will be described. The electric power consumption predictor 3 predicts electric power consumption by the consumer at the time subject to prediction based on the electric power consumption prediction model (behavioral state prediction model and behavioral electric power prediction model), the outdoor temperature-electric power relation (related parameter), and the outdoor temperature at the time subject to prediction that have been described above. FIG. 24 is a block diagram showing a functional structure of the electric power consumption predictor 3. As shown in FIG. 24, the electric power consumption predictor 3 includes a behavioral state predictor 31, an outdoor-temperature-depend electric power predictor 32, a behavioral electric power predictor 33, and a prediction value calculator 34.

The behavioral state predictor 31 acquires predicted outdoor temperature data (see FIG. 4) in the period when electric power consumption is to be predicted (for example, for one day) from the memory 4 to predict a behavioral state of the consumer at each time. The behavioral state predictor 31 acquires the behavioral state (area number) of the consumer from the behavioral state prediction model based on the time subject to prediction and the predicted outdoor temperature data at the time subject to prediction. The behavioral state (area number) thus acquired is stored in the memory 4 as a behavioral state of the consumer to be predicted at the time subject to prediction.

The outdoor-temperature-depend electric power predictor 32 refers to the consumer's behavioral state (area number) at each time predicted by the behavioral state predictor 31 to predict a state in which outdoor-temperature-depend electric power is used and outdoor-temperature-depend electric power at each time predicted by the behavioral state predictor 31 as follows.

ŷ_{AC}=ax+b [Formula 9]

Here, the “a” and “b” are related parameters and “x” is predicted outdoor temperature at the time subject to prediction. The outdoor-temperature-depend electric power predictor 32 predicts outdoor-temperature-depend electric power at each time for which outdoor-temperature-depend electric power is predicted not to be used as “0.” When the behavioral state predictor 31 predicts a behavioral state with reference to the behavioral state prediction model of FIG. 20, the outdoor-temperature-depend electric power predictor 32 predicts outdoor-temperature-depend electric power for the times of the areas 2 and 4 by the above formula and predicts outdoor-temperature-depend electric power for the times of the areas 1, 3, 5, and 6 as “0.” A prediction value of the outdoor-temperature-depend electric power thus predicted is stored in the memory 4.

The behavioral electric power predictor 33 refers to the behavioral state (area number) of the consumer at each time predicted by the behavioral state predictor 31 and acquires behavioral electric power for each time for which behavioral electric power is predicted to be used from the behavioral electric power prediction model. The behavioral electric power thus acquired is the behavioral electric power predicted at that time. In addition, the behavioral electric power predictor 33 predicts behavioral electric power at each time for which behavioral electric power is predicted not to be used as “0.” When the behavioral state predictor 31 predicts a behavioral state with reference to the behavioral state prediction model of FIG. 20, the behavioral electric power predictor 33 acquires behavioral electric power from the behavioral electric power prediction model for the times of the areas 1, 2, and 5 and predicts behavioral electric power for the times of the areas 3, 4, and 6 as “0.” A prediction value of the behavioral electric power thus predicted is stored in the memory 4.

The prediction value calculator 34 sums the prediction value of the outdoor-temperature-depend electric power predicted by the outdoor-temperature-depend electric power predictor 32, the prediction value of the behavioral electric power predicted by the behavioral electric power predictor 33, and the base electric power stored in the memory 4, to calculate a prediction value of electric power consumption by the consumer at each time in the period subject to prediction.

ŷ=μ_{Base}+ŷ_{act}+ŷ_{AC} [Formula 10]

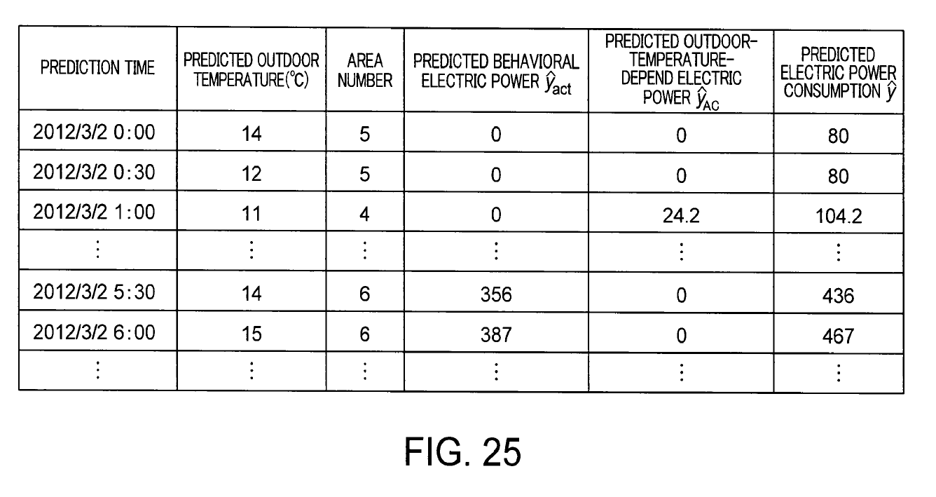

The prediction value of electric power consumption thus calculated is stored in the memory 4. FIG. 25 shows area numbers, outdoor temperature electric power, behavioral electric power, and electric power consumption predicted for predicted outdoor temperature data of FIG. 4.

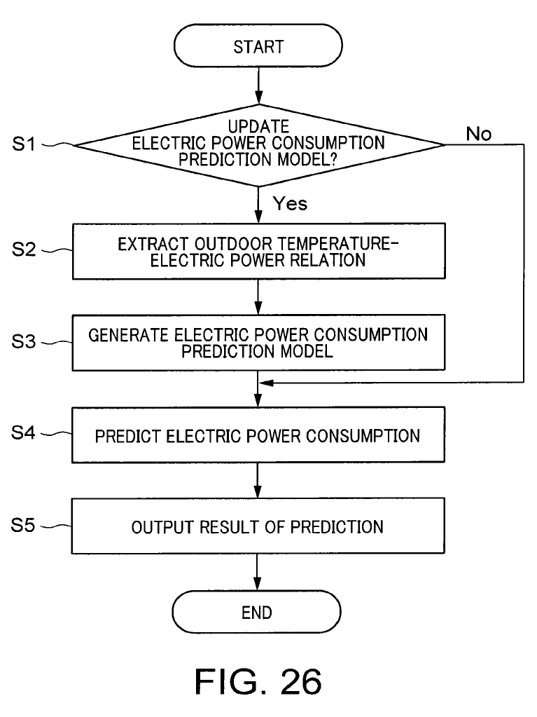

An operation of the electric power demand prediction system according to the present embodiment will be described below with reference to FIGS. 26 to 30. A case in which an operator of an electric power provider uses the electric power demand prediction system according to the present embodiment to predict electric power consumption by the consumer at the time subject to prediction will be described below. FIG. 26 is a flow chart showing the operation of the electric power demand prediction system according to the present embodiment.

First, whether or not the electric power consumption prediction model for predicting electric power consumption by the consumer needs to be updated is determined (Step S1). If the latest electric power consumption prediction model of the consumer subject to prediction is stored in the memory 4, it is not necessary to update the prediction model (No in Step S1). In this case, the electric power demand prediction process proceeds to Step S4 that is described later.

On the other hand, when the electric power consumption prediction model of the consumer subject to prediction is not stored in the memory 4 or when an electric power consumption trend of the consumer changed due to change of the season or the like, the electric power consumption prediction model is updated (Yes in Step S1). The determination of Step S1 may be done automatically by the electric power demand prediction system. This can be realized if the electric power consumption prediction model is to be updated when the time that has elapsed since the latest update time of the electric power consumption prediction model exceeds a predetermined time, for example. In addition, the determination of Step S1 may be done by the operator. In this case, the operator is only required to input necessity of update via an operation terminal of the electric power demand prediction system.

If the electric power consumption prediction model is to be updated (Yes in Step S1), an outdoor temperature-electric power relation is extracted first (Step S2). Next, an electric power consumption prediction model is generated based on the extracted outdoor temperature-electric power relation (Step S3). The generated electric power consumption prediction model is stored in the memory 4 and updated. Then, electric power consumption by the consumer in the period subject to prediction is predicted based on the updated prediction model (Step S4). In addition, if the electric power consumption prediction model is not to be updated (No in Step S1), electric power consumption by the consumer in the period subject to prediction is predicted based on the electric power consumption prediction model stored in the memory 4 (Step S4). Steps S2 to S4 described above will be described in detail later.

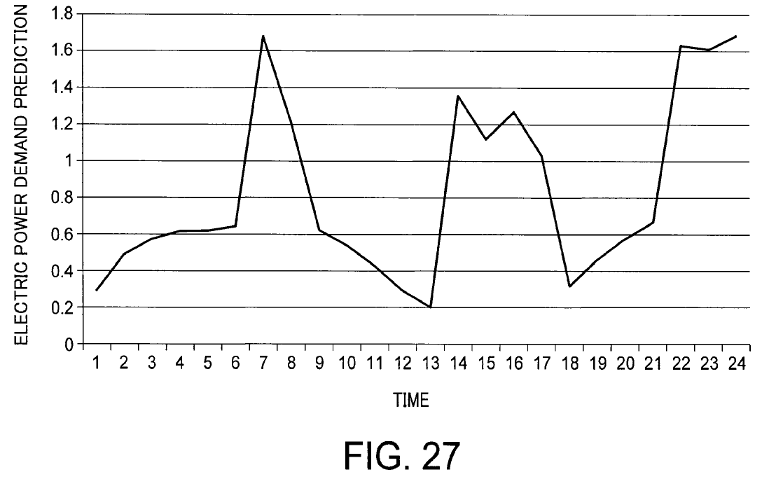

A result of the prediction in Step S4 is output on an output terminal of the electric power demand prediction system or on a monitor provided to an operation terminal (Step S5). FIG. 27 shows an example of an output display of the electric power demand prediction system. As shown in FIG. 27, the electric power demand prediction system may output a graph with the horizontal axis being the time subject to prediction and the vertical axis being the predicted electric power demand (electric power consumption). The electric power demand prediction system can output a result of the prediction in any formats such as graph in another format and tabular form.

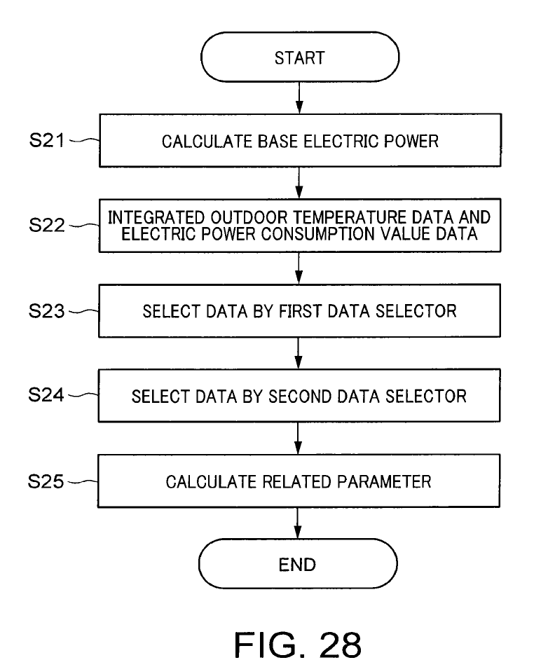

Next, Step S2 will be described. FIG. 28 is a flow chart showing the relation extraction process of Step S2 of FIG. 26. Step S2 is done by the relation extractor 1. First, the base electric power calculator 11 acquires electric power consumption value data of the consumer in the past predetermined period and calculates base electric power in that period (Step S21). The period in which electric power consumption value data is acquired may be stored in the memory 4 in advance or input by the operator via an operation terminal.

Once the base electric power is calculated, the outdoor temperature-electric power consumption integrator 12 couples the acquired electric power consumption value data and the outdoor temperature data stored in the memory 4 (Step S22). If the outdoor temperature data is not stored in the memory 4, the outdoor temperature-electric power consumption integrator 12 may acquire necessary outdoor temperature data from an external server or the like. The time relation of the outdoor temperature data and the electric power consumption value data to be integrated may be stored in the memory 4 in advance or input by the operator via an operation terminal.

Once the outdoor temperature data and the electric power consumption value data are integrated, the first data selector 13 selects electric power consumption value data with a high correlation between the outdoor temperature and electric power consumption (Step S23). The first data selector 13 selects electric power consumption value data based on time period designation data.

In addition, the second data selector 14 selects electric power consumption value data with electric power consumption larger than the base electric power μ_{Base} (or threshold electric power μₜₕ) stored in the memory 4 (Step S24). The Steps S22 to S24 described above can be done in any order.

The regression analyzer 15 extracts an outdoor temperature-electric power relation based on the base electric power calculated in the Step S21 and the electric power consumption value data selected in the Steps S22 to S24 and integrated to the outdoor temperature data (Step S25). That is, a regression analysis is performed with electric power consumption of the selected electric power consumption value data being an objective variable and the outdoor temperature being an explanatory variable to calculate a related parameter (threshold temperature or each parameter of regression formula). The calculated related parameter is stored in the memory 4.

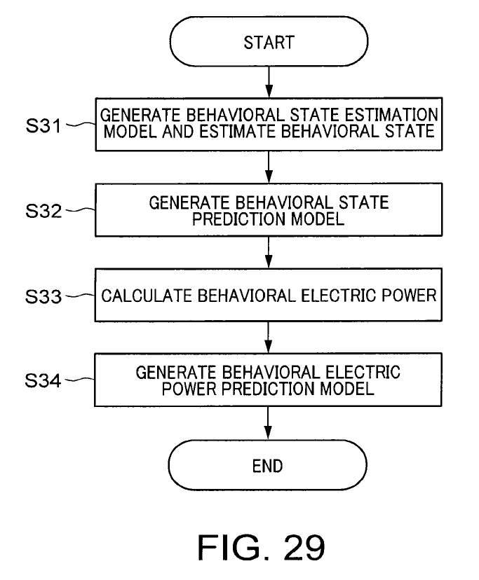

Next, Step S3 will be described. FIG. 29 is a flow chart showing the electric power consumption prediction model generation process of Step S3 of FIG. 26. Step S3 is done by the model generator 2. First, the behavioral state estimator 21 generates a behavioral state estimation model based on the related parameter calculated in Step S25 to estimate the consumer's past behavioral state (Step S31). Next, the behavioral state prediction model generator 22 generates a behavioral state prediction model based on the consumer's past behavioral state estimated by the behavioral state estimator 21 (Step S32). Next, the behavioral electric power calculator 23 calculates the consumer's past behavioral electric power based on the consumer's past behavioral state estimated by the behavioral state estimator 21 and the related parameter calculated in Step S25 (Step S33). Next, the behavioral electric power prediction model generator 24 generates a behavioral electric power prediction model based on the behavioral electric power calculated in Step S33 and the consumer's past behavioral state (Step S34). The behavioral state prediction model generated in Step S32 and the behavioral electric power prediction model generated in Step S34 are stored in the memory 4.

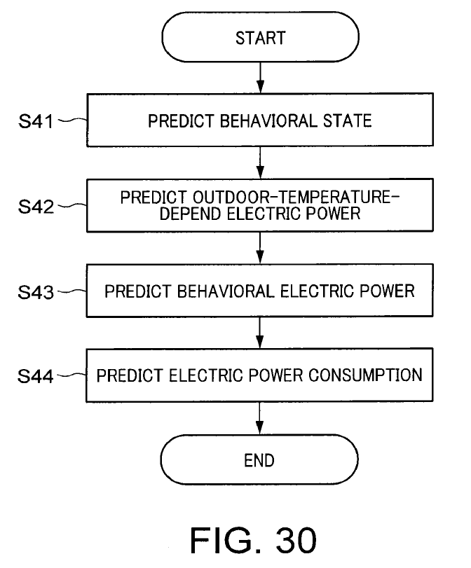

Next, Step S4 will be described. FIG. 30 is a flow chart showing the electric power consumption prediction process of Step S4 in FIG. 26. Step S4 is done by the electric power consumption predictor 3. First, the behavioral state predictor 31 acquires predicted outdoor temperature data in the period subject to prediction and refers to the behavioral state prediction model to predict the consumer's behavioral state at each time in the period subject to prediction (Step S41). The predicted outdoor temperature data in the period subject to prediction may be stored in the memory 4 in advance or acquired from an external server or the like by the behavioral state predictor 31. In addition, the intervals of each time subject to prediction may be stored in the memory 4 in advance or input by the operator via an operation terminal. Next, the outdoor-temperature-depend electric power predictor 32 predicts outdoor-temperature-depend electric power at each time in the period subject to prediction based on the consumer's behavioral state predicted by the behavioral state predictor 31, the predicted outdoor temperature data, and the related parameter (Step S42). Next, the behavioral electric power predictor 33 predicts behavioral electric power at each time in the period subject to prediction based on the consumer's behavioral state predicted by the behavioral state predictor 31 and the behavioral electric power prediction model (Step S43). Steps 42 and 43 can be done in any order. Next, the prediction value calculator 34 predicts electric power consumption in normal times at each time in the subject period and electric power consumption after demand response based on the base electric power stored in the memory 4, the prediction value of the outdoor-temperature-depend electric power calculated in Step S42, and the prediction value of the behavioral electric power calculated in Step S43 (Step S44). Each prediction value predicted in Steps S41 to S44 is stored in the memory 4 and output as a result of the prediction automatically or in response to the operator's request.

As described above, the electric power demand prediction system according to the present embodiment selects electric power consumption value data with a high correlation between the outdoor temperature and electric power consumption, that is, electric power consumption value data with small ratio of behavioral electric power included in electric power consumption, and extracts an outdoor temperature-electric power relation based on the selected electric power consumption value data. Therefore, the electric power demand prediction system according to the present embodiment can extract an outdoor temperature-electric power relation with high accuracy. In addition, since the electric power demand prediction system according to the present embodiment predicts electric power consumption based on the outdoor temperature-electric power relation thus extracted, it is possible to predict electric power consumption by the consumer with high accuracy. Prediction of electric power demand of the whole system with the use of electric power consumption by each consumer predicted by the electric power demand prediction system according to the present embodiment makes it possible to have an appropriate demand response and makes it possible to maintain the balance between electric power supply and demand in smart grid with high accuracy. In addition, according to the electric power demand prediction system of the present embodiment, since it is possible to predict electric power consumption for each consumer, an electric power provider can make a detailed plan of demand response to deal with prediction for each consumer.

### Second Embodiment

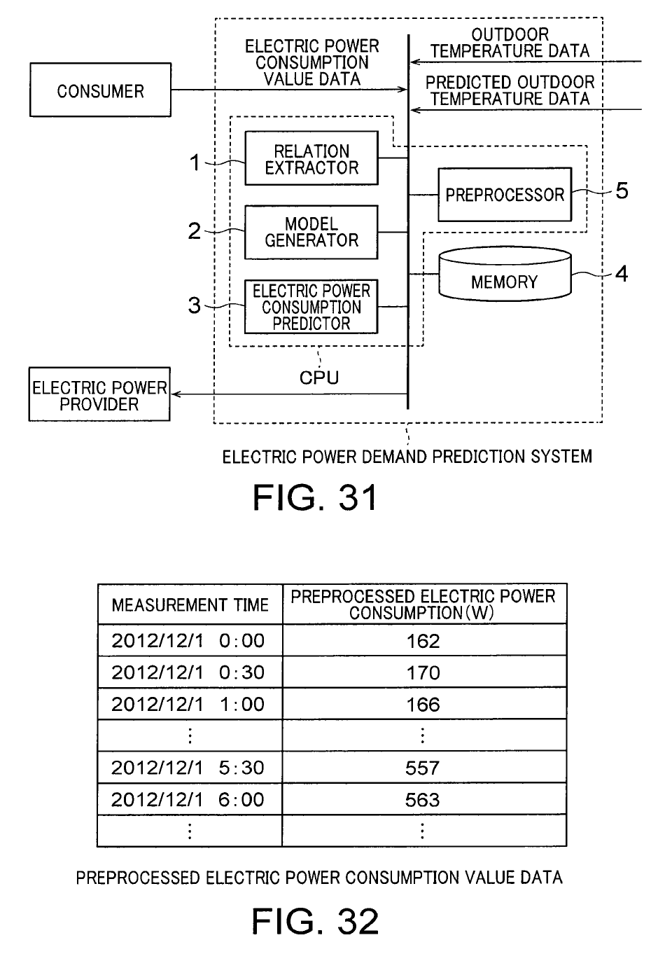

An electric power demand prediction system according to the second embodiment will be described below with reference to FIGS. 31 to 35. An electric power demand prediction system according to the present embodiment performs predetermined preprocessment on the electric power consumption value data and the outdoor temperature data stored in the memory 4, and predicts electric power consumption by a consumer based on the preprocessed electric power consumption value data and outdoor temperature data. FIG. 31 is a block diagram showing a functional structure of an electric power demand prediction system according to the present embodiment. As shown in FIG. 31, an electric power demand prediction system according to the present embodiment includes a relation extractor 1, a model generator 2, an electric power consumption predictor 3, and a memory 4. This structure is the same as that of the first embodiment. The electric power demand prediction system according to the present embodiment further includes a preprocessor 5 (preprocessing means).

The preprocessor 5 preforms preprocessment such as smoothing process, supplement process, and abnormal value removal process on the electric power consumption value data, the outdoor temperature data, and the like stored in the memory 4. Functions of the preprocessor 5 can be realized by executing a control program by a CPU. The preprocessor 5 may perform preprocessment only once or several times. Also, preprocessment may not be performed if not necessary. Performance and non-performance of preprocessment and the number of preprocessment may be input by an operator via an operation terminal or automatically determined by the electric power demand prediction system. In addition, preprocessment may be performed on only one of electric power consumption value data and outdoor temperature data. The preprocessed electric power consumption value data and outdoor temperature data are stored in the memory 4 as preprocessed data. FIG. 32 shows an example of preprocessed electric power consumption value data.

The smoothing process is process to smooth electric power consumption value data and outdoor temperature data. The smoothing process can be performed by calculating a moving mean value or a moving medium value of the electric power consumption value data or the outdoor temperature data stored in the memory 4 or by applying Nadaraya-Watson estimation or a spline function. The preprocessor 5 may calculate dispersion of the electric power consumption value data stored in the memory 4 and compare the calculated dispersion with the predetermined threshold value to determine whether or not to perform smoothing process.

The supplement process is a process to supplement damaged electric power consumption value data and outdoor temperature data. The supplement process can be performed by supplement damaged data with data adjacent to the damaged data or data estimated by the adjacent data. The preprocessor 5 may determine existence of damage of the electric power consumption value data and the outdoor temperature data stored in the memory 4 to determine whether or not to perform supplement process.

The abnormal value removal process is a process to remove data including an abnormal value from electric power consumption value data and outdoor temperature data. The abnormal value removal process can be realized by comparing electric power consumption or the outdoor temperature with the predetermined threshold value and removing electric power consumption value data or outdoor temperature data exceeding the threshold value. The preprocessor 5 may compare a maximum value and a minimum value of electric power consumption or the outdoor temperature with the predetermined threshold value to determine whether or not to perform abnormal value removal process. If abnormal value removal process is to be performed, it is preferable that supplement process be performed to supplement the removed data.

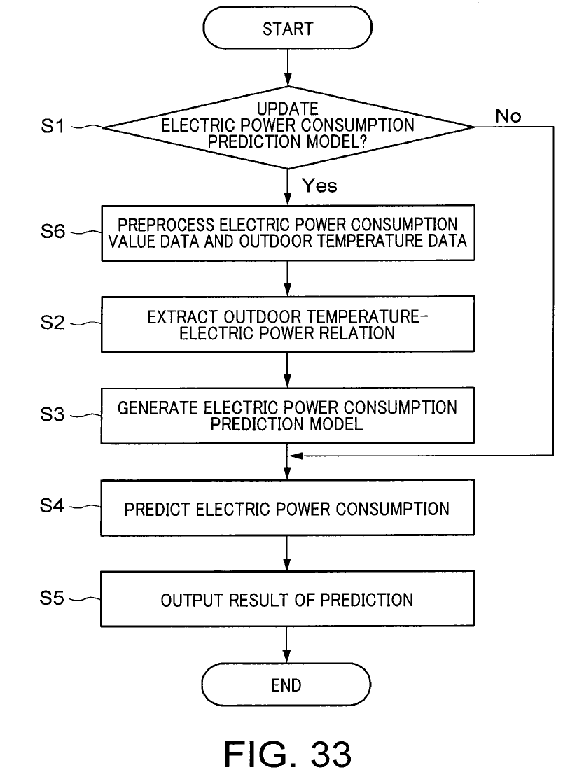

FIG. 33 is a flow chart showing an operation of the electric power demand prediction system according to the present embodiment. As shown in FIG. 33, in the present embodiment, if the electric power consumption prediction model is to be updated (Yes in Step S1), electric power consumption value data and outdoor temperature data are preprocessed by the preprocessor 5 first (Step S6). The preprocessed data is stored in the memory 4. Subsequent Steps S2 to S5 are the same as those of the first embodiment. However, in the present embodiment, the preprocessed electric power consumption value data or the preprocessed outdoor temperature data preprocessed by the preprocessor 5 is used instead of electric power consumption value data or outdoor temperature data in each step. If preprocessment has not been performed, electric power consumption value data or outdoor temperature data is used as with the first embodiment.

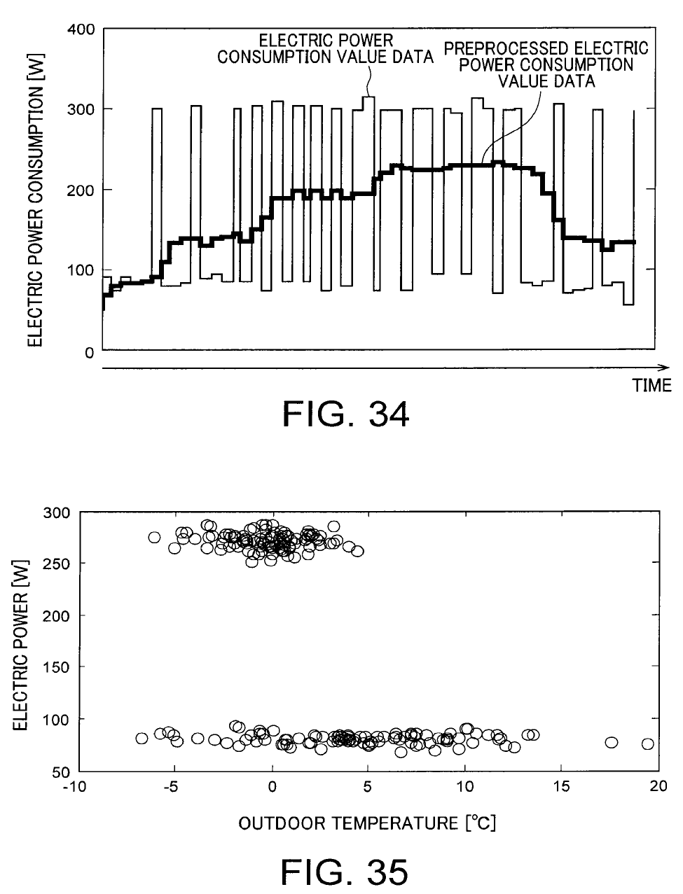

As described above, according to the electric power demand prediction system of the present embodiment, since electric power consumption value data and outdoor temperature data are smoothened and damaged data and an abnormal value are removed, it is possible to extract an outdoor temperature-electric power relation with higher accuracy. Accordingly, it is possible to improve accuracy of prediction of electric power consumption by the consumer. In particular, the present embodiment is useful when it is difficult to extract an outdoor temperature-electric power relation from original electric power consumption value data. For example, when outdoor-temperature-depend electric power of the consumer depends on equipment controlled by ON and OFF (such as air-conditioner), electric power consumption becomes a discrete value in an ON state and an OFF state of outdoor-temperature-depend electric power as shown in FIG. 34. Since electric power consumption does not vary in accordance with the outdoor temperature in such a case, a correlation between the outdoor temperature and electric power consumption-outdoor-temperature-depend electric power is unclear as shown in FIG. 35 and extraction of an outdoor temperature-electric power relation is difficult. However, according to the present embodiment, smoothing process on electric power consumption value data by the preprocessor 5 can generate preprocessed electric power consumption value data that continuously varies from the electric power consumption value data as a discrete value as shown in FIG. 34. Since a scattering diagram as shown in FIG. 11 can be obtained with the preprocessed electric power consumption value data that continuously varies, it is possible to easily extract an outdoor temperature-electric power relation.

### Third Embodiment

An electric power demand prediction system according to the third embodiment will be described below. In this embodiment, a first data selector 13 identifies a time period with a high correlation between the outdoor temperature and electric power consumption and selects electric power consumption value data in the identified time period. In this embodiment, a functional structure of an electric power demand prediction system is the same as that of the first embodiment.

First, the first data selector 13 acquires electric power consumption value data in a predetermined time period from the memory 4 to make a group of electric power consumption value data. Next, base electric power is subtracted from electric power consumption of electric power consumption value data included in the group that has been made. That is, electric power consumption value data shown in FIG. 13 is made. Next, an index indicating a correlation between the outdoor temperature x and electric power consumption y is calculated for the electric power consumption value data in the group from which base electric power is subtracted. For example, the first data selector 13 calculates a correlation coefficient between the outdoor temperature x and the electric power consumption y as such an index. For example, a correlation coefficient can be calculated with the following formula.

$$\frac{{\sum }_{i = 1}^{n} ( {x}_{i} - \overline{x} ) ( {y}_{i} - \overline{y} )}{\sqrt{{\sum }_{i = 1}^{n} {( {x}_{i} - \overline{x} )}^{2}} \sqrt{{\sum }_{i = 1}^{n} {( {y}_{i} - \overline{y} )}^{2}}} \qquad [ Formula 11 ]$$

The first data selector 13 makes groups of electric power consumption value data with the time period shifted by a predetermined time and calculates a correlation coefficient in the same way for each group. For example, groups of six hours with the time period shifted by one hour may be made such as a group of 0:00 to 6:00, a group of 1:00 to 7:00, and a group of 2:00 to 8:00. Duration of each group and the time to shift each group can be arbitrarily selected.

The first data selector 13 calculates indexes described above for several groups and compares the indexes of each group to identify the time period of the group with the highest correlation between the outdoor temperature x and the electric power consumption y. When a correlation coefficient is used as an index, the first data selector 13 calculates a correlation coefficient for several groups and identifies the time period of the group with the largest correlation coefficient as a time period with a high correlation between the outdoor temperature and electric power consumption. The identified time period is stored in the memory 4 as time period designation data shown in FIG. 9. The first data selector 13 selects electric power consumption value data based on the time period designation data thus selected. The first data selector 13 may identify a time period by calculating a rank correlation, a cross-correlation function, or the like for each group or identify a time period by another index indicating degree of similarity between variables.

As described above, according to the present embodiment, the first data selector 13 identifies the time period with a higher correlation between the outdoor temperature and electric power consumption and can select electric power consumption value data based on the identified time period. Accordingly, it is possible to extract a more accurate outdoor temperature-electric power relation and predict electric power consumption by a consumer with high accuracy.

The first data selector 13 can select a subject period of electric power consumption value data to be acquired for extracting an outdoor temperature-electric power relation by the same method as that for identifying the time period. For example, a correlation coefficient of electric power consumption value data of the subject period between January 1 and March 1 and a correlation coefficient of electric power consumption value data of the subject period between January 2 and March 2 are calculated and the subject period with a higher correlation coefficient may be identified. A time period with a larger correlation coefficient can be selected with the method described above for the electric power consumption value data of the subject period with a large correlation coefficient thus identified. Accordingly, it is possible to extract a much more accurate outdoor temperature-electric power relation.

### Fourth Embodiment

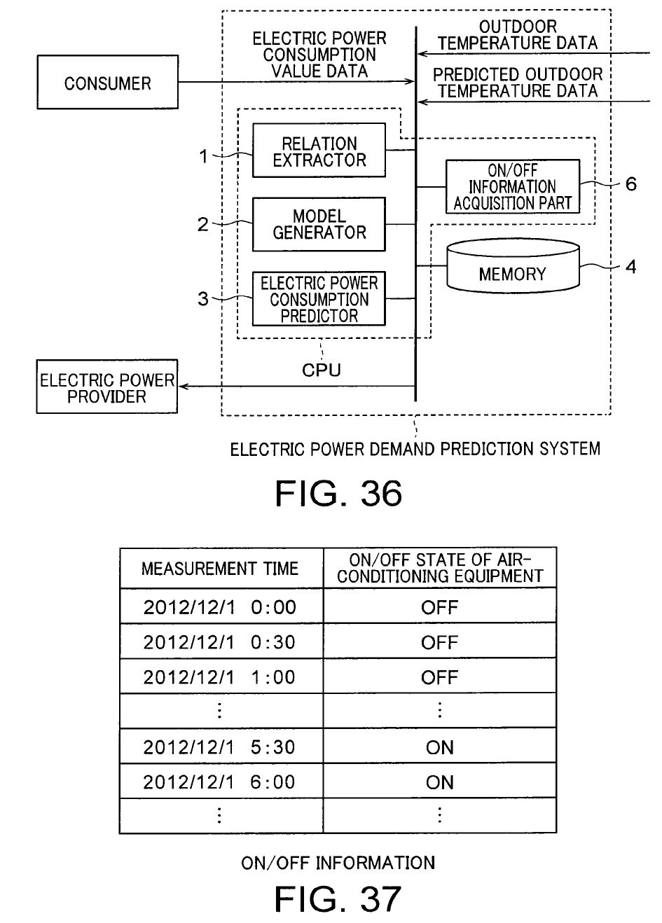

An electric power demand prediction system according to the fourth embodiment will be described below with reference to FIGS. 36 to 38. In the present embodiment, an electric power demand prediction system acquires ON/OFF information indicating use and non-use of at least part of outdoor-temperature-depend electric power. FIG. 36 is a block diagram showing a functional structure of an electric power demand prediction system according to the present embodiment. As shown in FIG. 36, an electric power demand prediction system according to the present embodiment includes a relation extractor 1, a model generator 2, an electric power consumption predictor 3, and a memory 4. This structure is the same as that of the first embodiment. The electric power demand prediction system according to the present embodiment further includes an ON/OFF information acquisition part 6.

The ON/OFF information acquisition part 6 acquires ON/OFF information from the consumer. The ON/OFF information is information indicating use and non-use of at least part of outdoor-temperature-depend electric power by the consumer, and information indicating whether or not air-conditioning equipment owned by the consumer is being used, for example. Functions of the ON/OFF information acquisition part 6 can be realized by executing a control program on a CPU. The ON/OFF information acquisition part 6 can acquire ON/OFF information from air-conditioning control equipment such as smart thermostat. Since a smart thermostat controls ON/OFF of air-conditioning equipment, the ON/OFF information acquisition part 6 can acquire ON/OFF information by acquiring a control signal transmitted to the air-conditioning equipment by the smart thermostat. The ON/OFF information acquired by the ON/OFF information acquisition part 6 is stored in the memory 4. FIG. 37 shows an example of the ON/OFF information stored in the memory 4. As shown in FIG. 37, the ON/OFF information is stored as history data indicating a use state (ON/OFF) of the air-conditioning equipment at each time.

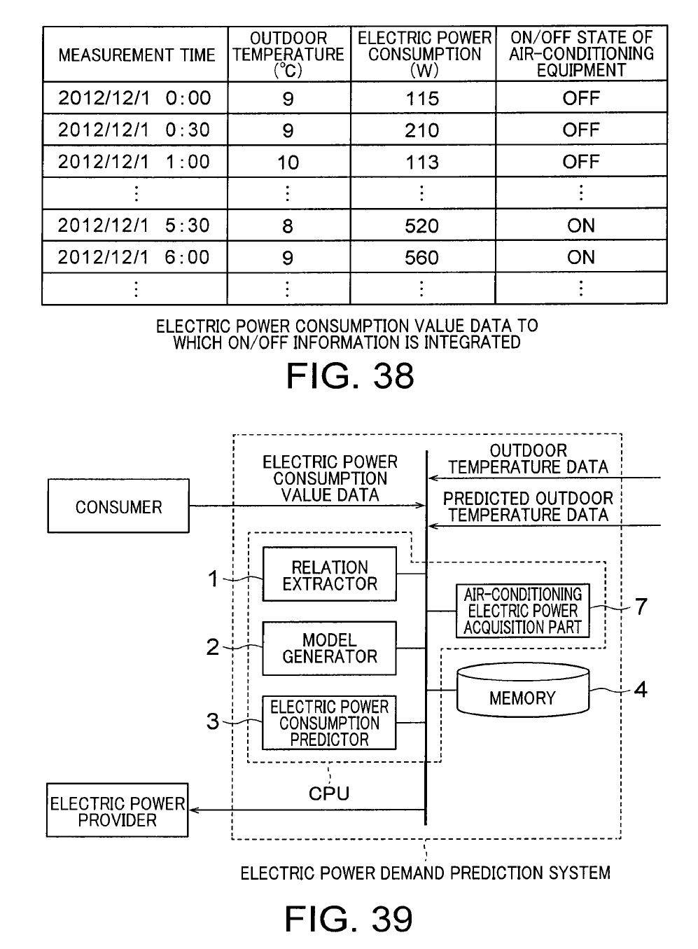

In the present embodiment, the relation extractor 1 can extract an outdoor temperature-electric power relation based on the ON/OFF information. First, an outdoor temperature-electric power consumption integrator 12 couples the outdoor temperature, electric power consumption, and the ON/OFF information according to times of each data. At this time, the electric power consumption value data and the ON/OFF information with the same time are integrated. Next, a regression analyzer 15 selects electric power consumption value data with air-conditioning use state of ON from the electric power consumption value data selected by the first data selector 13 and the second data selector 14, and performs a regression analysis based on the selected electric power consumption value data. Accordingly, it is possible to calculate a related parameter based on the electric power consumption value data in which outdoor-temperature-depend electric power is surely used. That is, it is possible to remove data in which outdoor-temperature-depend electric power is not included from the electric power consumption value data selected by the first data selector 13 and the second data selector 14. Therefore, the relation extractor 1 can extract an outdoor temperature-electric power relation with high accuracy. In particular, it is useful when the ON/OFF information indicates use and non-use of all of outdoor-temperature-depend electric power or of most of outdoor-temperature-depend electric power. FIG. 38 shows an example of electric power consumption value data to which ON/OFF information is integrated.

In the present embodiment, the model generator 2 can estimate a behavioral state of the consumer based on ON/OFF information. First, a behavioral state estimator 21 estimates the consumer's past behavioral state based on a behavioral state estimation model. Next, the behavioral state estimator 21 refers to the ON/OFF information to correct a use state of the estimated outdoor-temperature-depend electric power. For example, it is possible to correct the estimated area number (behavioral state) from the area 1 (outdoor-temperature-depend electric power OFF) to the area 4 (outdoor-temperature-depend electric power ON) or correct from the area 2 or the area 4 to the area 1. Accordingly, it is possible to more accurately estimate the consumer's past behavioral state. In particular, it is useful when the ON/OFF information indicates use and non-use of all of outdoor-temperature-depend electric power or of most of outdoor-temperature-depend electric power. A behavioral state may be corrected with a rule different from the rule described above in consideration of the relation between outdoor-temperature-depend electric power and behavioral electric power. In addition, the rule of correction of a behavioral state may be stored in the memory 4 in advance or input by an operator via an operation terminal.

### Fifth Embodiment

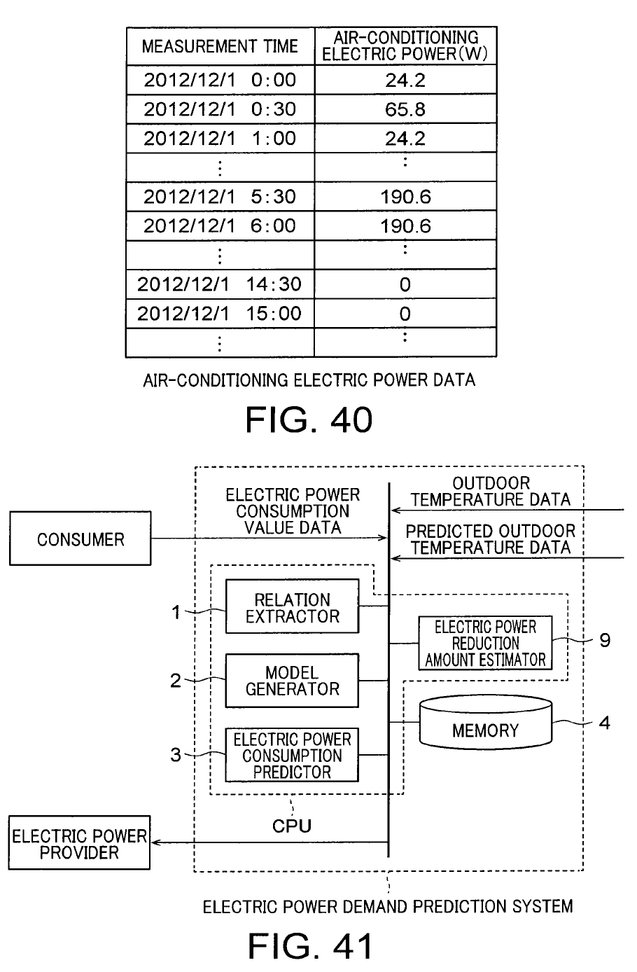

An electric power demand prediction system according to the fifth embodiment will be described below with reference to FIGS. 39 and 40. In the present embodiment, an electric power demand prediction system acquires part of outdoor-temperature-depend electric power of a consumer. FIG. 39 is a block diagram showing a functional structure of an electric power demand prediction system according to the present embodiment. As shown in FIG. 39, an electric power demand prediction system according to the present embodiment includes a relation extractor 1, a model generator 2, an electric power consumption predictor 3, and a memory 4. This structure is the same as that of the first embodiment. The electric power demand prediction system according to the present embodiment further includes an air-conditioning electric power acquisition part 7.

The air-conditioning electric power acquisition part 7 acquires air-conditioning electric power data indicating air-conditioning electric power that is part of outdoor-temperature-depend electric power of the consumer. Air-conditioning electric power data is, for example, data indicating electric power consumption of one air-conditioning equipment when the consumer owns several air-conditioning equipment that consumes outdoor-temperature-depend electric power. Since air-conditioning electric power is only required to be part of outdoor-temperature-depend electric power, it is not limited to electric power consumption of air-conditioning equipment. For example, the air-conditioning electric power acquisition part 7 can acquire air-conditioning electric power data from a sub-breaker or the like that measures air-conditioning electric power aside from overall electric power consumption by the consumer. Functions of the air-conditioning electric power acquisition part 7 can be realized by executing a control program on a CPU. FIG. 40 shows an example of air-conditioning electric power data. As shown in FIG. 40, air-conditioning electric power data is stored in the memory 4 as history data sorted in chronological order,

In the present embodiment, the relation extractor 1 can extract an outdoor temperature-electric power relation based on air-conditioning electric power data. For example, a base electric power calculator 11 may subtract air-conditioning electric power of air-conditioning electric power data from electric power consumption of electric power consumption value data to calculate base electric power based on the electric power consumption from which the air-conditioning electric power is subtracted. Accordingly, outdoor-temperature-depend electric power included in base electric power is reduced and base electric power can be accurately calculated.

In addition, the electric power demand prediction system may compare air-conditioning electric power of air-conditioning electric power data with the predetermined threshold value to determine that outdoor-temperature-depend electric power is ON when the air-conditioning electric power is larger than the threshold value and that outdoor-temperature-depend electric power is OFF when the air-conditioning electric power is equal to or less than the threshold value. Accordingly, it is possible to generate ON/OFF information of outdoor-temperature-depend electric power from air-conditioning electric power data. The relation extractor 1 and the model generator 2 can perform the same process as that in the fourth embodiment with the generated ON/OFF information. That is, the relation extractor 1 can extract an outdoor temperature-electric power relation based on the ON/OFF information and the model generator 2 can estimate a behavioral state of the consumer based on the ON/OFF information.

### Sixth Embodiment

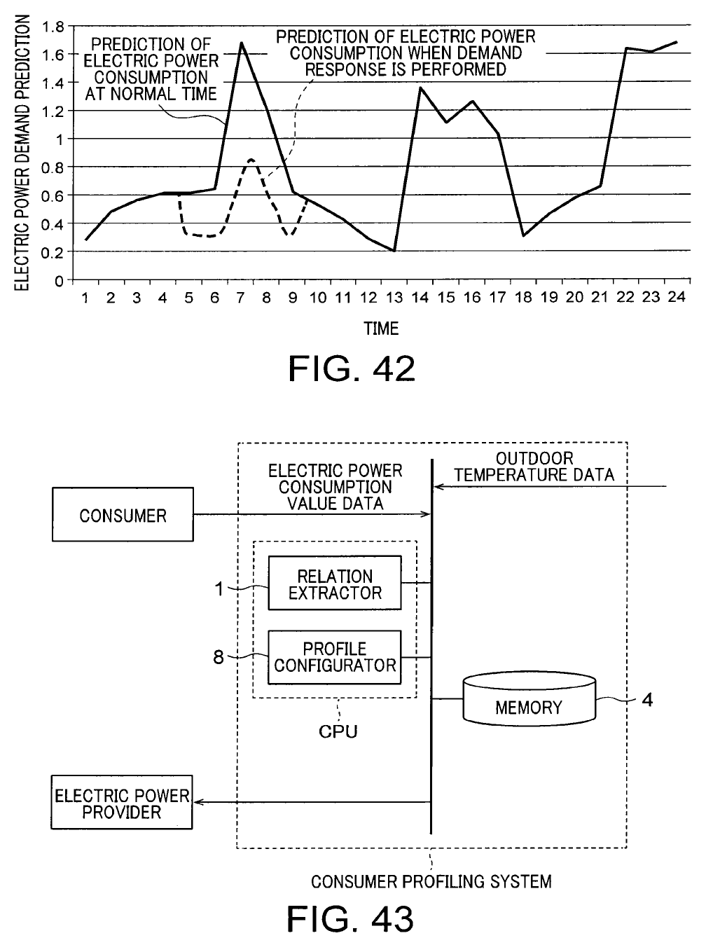

An electric power demand prediction system according to the sixth embodiment will be described below with reference to FIGS. 41 and 42. In the present embodiment, an electric power demand prediction system estimates an amount of reduction in electric power when performing demand response, and predicts electric power consumption by the consumer after reduction. This is because, when an electric power provider predicts electric power consumption on a particular day and determines that electric power is tight on that day, one wants to predict an effect of demand response as well. In the present embodiment, a case in which an electric power provider can directly control air-conditioning equipment and the like of the consumer by an air-conditioning equipment external control device such as a smart thermostat will be described; however, this can be realized without an air-conditioning equipment external control device.

FIG. 41 is a block diagram showing a functional structure of an electric power demand prediction system according to the present embodiment. As shown in FIG. 41, an electric power demand prediction system according to the present embodiment includes a relation extractor 1, a model generator 2, an electric power consumption predictor 3, and a memory 4. This structure is the same as that of the first embodiment. In the present embodiment, the electric power demand prediction system further includes an electric power reduction amount estimator 9.

The electric power reduction amount estimator 9 estimates an amount of reduction in electric power consumed by the consumer when demand response is performed. The electric power reduction amount estimator 9 can estimate an amount of reduction in electric power according to a plan to control air-conditioning equipment and the like via an air-conditioning equipment control device. For example, air-conditioning equipment or the like is driven intermittently with 50% of power being off, and the electric power reduction amount estimator 9 can calculate an amount of reduction in electric power with the following formula.

r=½×ŷ_{AC} [Formula 12]

Here, “r” is a prediction value of an amount of reduction in electric power. Similarly, when air-conditioning equipment or the like is driven intermittently with P % of power being off, the electric power reduction amount estimator 9 can calculate an amount of reduction in electric power with the following formula.

$$r = \frac{P}{100} \times {\hat{y}}_{A C} \qquad [ Formula 13 ]$$

Moreover, when the set temperature of a heater in the winter season is lowered by Tₙ° C., the electric power reduction amount estimator 9 can calculate an amount of reduction in electric power with the following formula.

r=−aTₙ [Formula 14]

Here, “a” is a related parameter described above. Similarly, when the set temperature of cooling air-conditioning equipment in the summer season is increased by Tₙ° C., the electric power reduction amount estimator 9 can calculate an amount of reduction in electric power with the following formula.

r=aTₙ [Formula 15]

In addition, the electric power reduction amount estimator 9 may set another value as “r” in accordance with types of demand response or time periods. For example, when an air-conditioning equipment external control device is not introduced by the consumer, an operator may set an appropriate value as P of the intermittent driving described above. Moreover, electric power consumption actually measured when demand response is performed may be compared with electric power consumption at the same time as demand response predicted by the electric power consumption predictor 3 as in the first embodiment to obtain the difference as an actual amount of reduction in electric power, and the actual amount may be stored in the memory 4. Then, the statistic of the accumulated actual amounts of reduction in electric power may be taken to calculate “r”. For example, a mean value or a mode value can be used for taking the statistic. In addition, any regression method such as neural network and support vector regression can be used with the weather, the temperature, the time period, or the like being an explanatory variable. The statistic may be taken for each type of demand response. In addition, an operator of an electric power provider may set any value as “r” via an input interface.

In the present embodiment, the electric power consumption predictor 3 may predict electric power consumption at the time when demand response is performed in addition to prediction of electric power consumption at the normal time and store a prediction result in the memory 4. Prediction of electric power consumption at the time when demand response is performed can be calculated with the following formula by subtracting “a” predicted amount of reduction in electric power output by the electric power reduction amount estimator 9 from prediction of electric power consumption at the normal time.

ŷ_{z}=ŷ−r=μ_{Base}+ŷ_{act}+ŷ_{AC}−r [Formula 16]

Prediction of electric power consumption at the time when demand response is performed is output on an output terminal or on a monitor provided to an operation terminal as necessary. For example, as shown in FIG. 42, prediction of electric power consumption at the normal time can be displayed over prediction of electric power consumption at the time when demand response is performed.

Consumer groups in which electric power is to be reduced include various types such as the whole area, a block being one branch for electric distribution, and each consumer, and different DR scenarios are required for each of them. Since outdoor temperature electric power is analyzed and reduction in outdoor temperature electric power is predicted for small groups such as each consumer in the present embodiment instead of predicting demand or reduction after whole electric power is accumulated, various DR scenarios can be dealt with. For example, prediction of reduction for mixed DR scenarios in a consumer group is possible, such as one consumer intermittently driving air-conditioner by 50%, another consumer turning down air-conditioner by 100%, and still another consumer changing air-conditioner temperature setting by 2° C. with a control device for DR such as smart thermostat.

### (Consumer Profiling System)

An embodiment of a consumer profiling system will be described with reference to FIG. 43. A consumer profiling system according to the present embodiment extracts an outdoor temperature-electric power-relation based on electric power consumption value data of a consumer such as residential house and shop and outdoor temperature data, and sets a profile to the consumer based on the extracted outdoor temperature-electric power relation. The profile of each consumer thus set can be used for providing information or offering services to the consumer, for example. FIG. 43 is a block diagram showing a functional structure of a consumer profiling system according to the present embodiment. As shown in FIG. 43, a consumer profiling system according to the present embodiment acquires electric power consumption value data from the consumer and acquires outdoor temperature data from outside the system. Electric power consumption value data and outdoor temperature data used by the consumer profiling system are the same as electric power consumption value data and outdoor temperature data used by the electric power demand prediction system.

Next, a functional structure of a consumer profiling system will be described. As shown in FIG. 43, a consumer profiling system according to the present embodiment includes a relation extractor 1 (extraction means) for extracting a relation between the outdoor temperature and outdoor-temperature-depend electric power and a memory 4 for storing various information. This structure is the same as that of an electric power demand prediction system. A consumer profiling system further includes a profile configurator 8 (profile setting means) for setting a profile to the consumer based on the outdoor temperature-electric power relation extracted by the relation extractor 1. A consumer profiling system with the above structure can be realized with a computer device including a CPU or a memory used as basic hardware. In more detail, functions of the relation extractor 1 and the profile configurator 8 can be realized by executing a control program on a CPU. In addition, a memory device such as non-volatile memory and external memory device can be used as the memory 4.

The profile configurator 8 sets a profile to the consumer based on the outdoor temperature-electric power relation (related parameter) extracted by the relation extractor 1. A profile is qualitative information indicating the consumer's properties. First, a method by which the profile configurator 8 sets a profile based on the threshold temperature Tₜₕ will be described.

If the subject period for which the outdoor temperature-electric power relation is extracted is the winter season, the profile configurator 8 compares the threshold temperature Tₜₕ with the cold threshold value Tₛ when the relation extractor 1 calculates the threshold temperature Tₜₕ. The cold threshold value Tₛ is the outdoor temperature at which outdoor-temperature-depend electric power (for example, heating equipment) is assumed to start to be used and may be stored in the memory 4 in advance or input by an operator. In contrast, the threshold temperature Tₜₕ in the winter season is the temperature at which the consumer starts to use outdoor-temperature-depend electric power (for example, heating equipment). That is, the case with Tₜₕ>Tₛ is the case in which the outdoor temperature at which the consumer starts to use heating equipment or the like is higher than the outdoor temperature at which heating equipment or the like is assumed to start to be used. Therefore, in the case with Tₜₕ>Tₛ, the profile configurator 8 sets a profile of “sensitive to cold” to the consumer.

Similarly, if the subject period for which the outdoor temperature-electric power relation is extracted is the summer season, the profile configurator 8 compares the threshold temperature Tₜₕ with the hot threshold value Tₐ when the relation extractor 1 calculates the threshold temperature Tₜₕ. The hot threshold value Tₐ is the temperature at which outdoor-temperature-depend electric power (for example, cooling equipment) is assumed to start to be used and may be stored in the memory 4 in advance or input by an operator. In contrast, the threshold temperature Tₜₕ in the summer season is the temperature at which the consumer starts to use outdoor-temperature-depend electric power (for example, cooling equipment). That is, the case with Tₜₕ<Tₐ is the case in which the outdoor temperature at which the consumer starts to use cooling equipment or the like is higher than the outdoor temperature at which cooling equipment or the like is assumed to start to be used. Therefore, in the case with Tₜₕ<Tₐ the profile configurator 8 sets a profile of “sensitive to heat” to the consumer.

The profile of the consumer thus set is stored in the memory 4. The profile of the consumer is transmitted to an electric power supplier for example, and can be used as one of criteria for selecting a consumer for which demand response is performed. In addition, a business operator who has acquired a profile of a consumer can use the profile of the consumer for providing information or offering services in accordance with the profile. For example, a business operator can offer purchase of floor heating equipment and renovation of the house to improve heat insulating properties to a consumer with a profile of “sensitive to cold,”

The cold threshold value Tₛ (hot threshold value Tₐ) described above may be set based on the threshold temperature Tₜₕ of several consumers. In this case, after the relation extractor 1 calculates the threshold temperature Tₜₕ of several consumers, the profile configurator 8 takes the statistic of the calculated threshold temperature Tₜₕ to set the cold threshold value Tₛ (hot threshold value Tₐ). For example, the relation extractor 1 can arrange several threshold temperatures Tₜₕ in ascending order and set the threshold temperatures Tₜₕ in the lower (upper) 25% as the cold threshold value Tₛ (hot threshold value Tₐ). Accordingly, the cold threshold value Tₛ (hot threshold value Tₐ) is set so that the profile of “sensitive to cold” (“sensitive to heat”) is set to 25% of the consumers out of all consumers for which the threshold temperature Tₜₕ is calculated. The threshold temperature Tₜₕ to be set as the cold threshold value Tₛ (hot threshold value Tₐ) is not limited to the threshold temperature Tₜₕ corresponding to the lower (upper) 25% of the whole calculated threshold value Tₜₕ and may be the threshold temperature Tₜₕ corresponding to any ratio.

In addition, as a method for taking the statistic, a method in which several calculated threshold temperatures Tₜₕ are clustered into several clusters and the outdoor temperature between the threshold temperature Tₜₕ of the cluster with the highest (lowest) threshold temperature Tₜₕ and the threshold temperature Tₜₕ of the cluster with the second highest (lowest) threshold temperature Tₜₕ is set as a cold threshold value Ts (hot threshold value Tₐ) is also possible. Any data clustering method such as k-means method may be employed for clustering. Accordingly, a profile of “sensitive to cold” (“sensitive to heat”) can be set to the consumer clustered into the cluster with the highest (lowest) threshold temperature Tₜₕ. The profile configurator 8 can also set a cold threshold value Tₛ (hot threshold value Tₐ) so that a profile of “sensitive to cold” (“sensitive to heat”) is set to the consumer included in the clusters with the highest (lowest) to the Nth highest (lowest) threshold temperature.

Next, a method in which the profile configurator 8 sets a profile based on base electric power μ_{Base} and a slope “a” of a regression line will be described. When the relation extractor 1 calculates base electric power μ_{Base}, the profile configurator 8 compares the base electric power μ_{Base} with the base electric power threshold value μ_{Base0}. The base electric power threshold value μ_{Base0} may be stored in the memory 4 in advance or input by an operator. In the case with μ_{Base}>μ_{Base0}, the profile configurator 8 determines that base electric power of the consumer is large and sets a profile of “large base electric power.”

Similarly, when the relation extractor 1 calculates a slope “a” of a regression line, the profile configurator 8 compares the slope “a” with the slope threshold value a₀. The slope threshold value a₀ may be stored in the memory 4 in advance or input by an operator. When the electric power consumption value data used to extract an outdoor temperature-electric power relation is the electric power consumption value data is the winter season, the slope “a” is a negative value. Therefore, in the case with a<a₀, the profile configurator 8 determines that outdoor-temperature-depend electric power of the consumer is large and sets a profile of “large outdoor-temperature-depend electric power.” On the other hand, when the electric power consumption value data used to extract an outdoor temperature-electric power relation is the electric power consumption value data in the summer season, the slope “a” is a positive value. Therefore, in the case with a>a₀, the profile configurator 8 determines that outdoor-temperature-depend electric power of the consumer is large and sets a profile of “large outdoor-temperature-depend electric power.”

In addition, the profile configurator 8 can set a profile of “large house” to the consumer with a base electric power threshold value μ_{BaseD} and a slope threshold value a₀. When the profile of “large base electric power and large outdoor-temperature-depend electric power” is set to the consumer, it is highly possible that the consumer has air-conditioning equipment with large output and home electrical appliances with large standby electric power such as refrigerator. It is assumed that the house of such a consumer is large. The profile configurator 8 sets a profile of “large house” to such a consumer. The base electric power threshold value μ_{Base0} and the slope threshold value a₀ for setting a profile of “large house” may be different from the threshold value for setting profiles of “large base electric power” and “large outdoor-temperature-depend electric power.”

The profile of the consumer thus set is stored in the memory 4. The profile of the consumer is transmitted to an electric power supplier for example, and can be used as one of criteria to select a consumer of a family unit for which demand response is to be performed. For example, since it is assumed that electric power demand can be reduced more for a consumer with a parameter of “large house,” an electric power supplier can preferentially ask that consumer to reduce electric power. In addition, a business operator that has acquired the profile of the consumer can provide information or offer services to the consumer according to the profile of the consumer. For example, a business operator can recommend “home keeper” or “robot-type self-running vacuum cleaner” to the consumer with the parameter of “large house.”

The base electric power threshold value μ_{Base0} and the slope threshold value a₀ may be set based on base electric power μ_{Base} and a slope “a” of several consumers as with the cold threshold value Tₛ and the hot threshold value Tₐ. For example, a value corresponding to any lower or upper ratio of several base electric power μ_{Base} and slope “a” may be set as a base electric power threshold value μ_{Base0} and a slope threshold value a₀. In addition, the base electric power threshold value μ_{Base0} and the slope threshold value a₀ may be set by clustering described above. Moreover, the base electric power threshold value μ_{Base0} and the slope threshold value a₀ may be set by two-dimensional clustering with a pair of data (a, μBase) of each consumer. In this case, first, the profile configurator 8 clusters several calculated (a, μBase) into several clusters. Next, (a, μBase) is set so that a profile of “large house” is set to the consumer included in the cluster with the largest to the Nth largest slope “a” and base electric power μBase. In addition, the profile configurator 8 may calculate centers of each cluster and compare the calculated centers to set the base electric power threshold value μ_{Base0} and the slope threshold value a₀.

In addition, the profile configurator 8 can also set a profile of “air-conditioning ON when not present” to the consumer with the behavioral state of the consumer. When the profile of “air-conditioning ON when not present” is set, it is highly possible that the consumer is consuming wasted electric power. Such information can be used as preliminary information for an electric power provider or a demand response business operator to ask for reduction in electric power.

The profile configurator 8 sets a profile of “air-conditioning ON when not present” based on a ratio of time to use outdoor-temperature-depend electric power when the consumer is not present. For example, “time when the consumer is not present” is a time period with behavioral electric power OFF (areas 3, 4, and 6 in FIG. 17) except the sleeping time period (for example, 23:30 to 9:00), and “time to use outdoor-temperature-depend electric power” is a time period with outdoor-temperature-depend electric power equal to or larger than the threshold value set in advance. The profile configurator 8 extracts “time when the consumer is not present” from an arbitrary period (for example, one month), extracts “time to use outdoor-temperature-depend electric power” at the extracted “time when the consumer is not present,” and calculates a ratio of “time to use outdoor-temperature-depend electric power” with respect to “time when the consumer is not present.” The profile configurator 8 compares the calculated ratio with the threshold value set in advance and sets a profile of “outdoor-temperature-depend electric power ON when not present” to the consumer when the calculated ratio is larger than the threshold value. “Time to use outdoor-temperature-depend electric power” described above may be a time period in which outdoor-temperature-depend electric power is ON (areas 2 and 4 in FIG. 17).

When the profile configurator 8 sets a profile based on a behavioral state of the consumer as described above, it is preferable that a consumer profiling system includes a model generator 2 described above. The profile configurator 8 can set a profile based on a behavioral state of the consumer with the outdoor-temperature-depend electric power data (see FIG. 21) and the behavioral electric power data (see FIG. 22) generated by the model generator 2. Alternatively, a consumer profiling system may not include a model generator 2 and may additionally include a function to generate outdoor-temperature-depend electric power data and behavioral electric power data or behavioral state data.

The profile configurator 8 can also set a profile of “outdoor-temperature-depend electric power is stably ON in electric power consumption peak time period” to a consumer with a behavioral state of the consumer. “Electric power consumption peak time period” mentioned here is a peak time period set in advance (for example, 5:00 to 9:00 in the winter season). It is assumed that the consumer with such a profile has a high economic effect of reduction in electric power. That is, peak electric power can be effectively suppressed by asking such a consumer to reduce electric power.

The profile configurator 8 calculates a ratio of a time period of “outdoor-temperature-depend electric power ON” with respect to “electric power consumption peak time period” and compares the calculated ratio with the threshold value set in advance to set a profile of “outdoor-temperature-depend electric power is stably ON in electric power consumption peak time period.” The time period of “outdoor-temperature-depend electric power ON” may be a time period with outdoor-temperature-depend electric power larger than the threshold value set in advance or a time period when outdoor-temperature-depend electric power is ON (areas 2 and 4 in FIG. 17).

The profile configurator 8 can also combine a profile using a behavioral state and a profile using an outdoor temperature-electric power relation described above to set a profile of “outdoor-temperature-depend electric power ON and large outdoor-temperature-depend electric power when not present” or “outdoor-temperature-depend electric power is stably ON and large outdoor-temperature-depend electric power in electric power consumption peak time period” to a consumer.

With the configuration described above, according to the consumer profiling system of the present embodiment, a predetermined profile can be set to a consumer based on an outdoor temperature-electric power relation. An electric power supplier or a business operator can supply information or offer services in accordance with the profile of the consumer with the profile that has been set.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An electric power demand prediction system, comprising:
an extractor to select electric power consumption value data included in a certain period out of a consumer's past electric power consumption value data and to extract an outdoor temperature-electric power relation that is a relation between an outdoor temperature and outdoor-temperature-depend electric power varying in accordance with the outdoor temperature out of electric power consumption based on the selected electric power consumption value data;
a model generator to generate an electric power consumption prediction model which predicts electric power consumption by the consumer in accordance with the outdoor temperature based on the outdoor temperature-electric power relation extracted by the extractor; and
a predictor to predict electric power consumption by the consumer at a time subject to prediction based on the electric power consumption prediction model generated by the model generator and the outdoor temperature at the time subject to prediction.

2. The electric power demand prediction system according to claim 1, wherein the extractor selects electric power consumption value data included in a period determined in advance.

3. The electric power demand prediction system according to claim 1, wherein the extractor generates several groups of electric power consumption value data, calculates indexes indicating degree of a correlation between an outdoor temperature and electric power consumption in each group, and compares the indexes to select electric power consumption value data included in a group with the highest correlation between the outdoor temperature and the electric power consumption.

4. The electric power demand prediction system according to claim 1, wherein the extractor selects electric power consumption value data in a time period in which the consumer is asleep or in a time period in which the consumer is absent from home.

5. The electric power demand prediction system according to claim 1, wherein the extractor calculates base electric power as a reference of electric power consumption by the consumer based on the electric power consumption value data and selects the electric power consumption value data with electric power consumption larger than the base electric power.

6. The electric power demand prediction system according to claim 1, wherein the extractor performs a regression analysis based on the electric power consumption value data with an outdoor temperature as an explanatory variable and outdoor-temperature-depend electric power as an objective variable and extracts the outdoor temperature-electric power relation based on an analysis result.

7. The electric power demand prediction system according to claim 5, wherein the model generator estimates a behavioral state that is a state of use of electric power by the consumer based on the outdoor temperature-electric power relation, generates a behavioral state prediction model for predicting a behavioral state of the consumer in accordance with an outdoor temperature based on the estimated behavioral state, calculates behavioral electric power that is residual electric power obtained by subtracting outdoor-temperature-depend electric power and base electric power from electric power consumption by the consumer, and predicts behavioral electric power of the consumer in each behavioral state based on the behavioral electric power and the behavioral state.

8. The electric power demand prediction system according to claim 7, wherein the model generator generates a behavioral state estimation model which estimates a behavioral state of the consumer in accordance with an outdoor temperature and electric power consumption based on the outdoor temperature-electric power relation.

9. The electric power demand prediction system according to claim 7, wherein the model generator takes the statistic of the estimated behavioral state to generate the behavioral state prediction model.

10. The electric power demand prediction system according to claim 7, wherein the model generator calculates outdoor-temperature-depend electric power based on the outdoor temperature-electric power relation and calculates behavioral electric power by subtracting the calculated outdoor-temperature-depend electric power and base electric power from electric power consumption by the consumer.

11. The electric power demand prediction system according to claim 7, wherein the behavioral state includes at least one of a state in which the consumer is using outdoor-temperature-depend electric power, a state in which the consumer Is not using outdoor-temperature-depend electric power, a state in which the consumer is using behavioral electric power, and a state in which the consumer is not using behavioral electric power.

12. The electric power demand prediction system according to claim 1, further comprising a preprocessor to perform at least one of smoothing process, supplement process, and abnormal value removal process on the electric power consumption value data to generate preprocessed electric power consumption value data.

13. The electric power demand prediction system according to claim 1, wherein the extractor acquires ON/OFF information indicating existence and non-existence of at least part of outdoor-temperature-depend electric power of the consumer and extracts the outdoor temperature-electric power relation based on the ON/OFF information and the electric power consumption value data.

14. The electric power demand prediction system according to claim 13, wherein the model generator estimates a behavioral state based on the ON/OFF information and the outdoor temperature-electric power relation.

15. The electric power demand prediction system according to claim 1, wherein the extractor acquires part of outdoor-temperature-depend electric power of the consumer and extracts the outdoor temperature-electric power relation based on the acquired outdoor-temperature-depend electric power and the electric power consumption value data.

16. The electric power demand prediction system according to claim 1, further comprising an electric power reduction amount estimator to estimate an amount of reduction in electric power by the consumer when demand response is performed based on the electric power consumption by the consumer at the time subject to prediction predicted by the predictor, wherein
the predictor predicts electric power consumption by the consumer at the time subject to prediction when demand response is performed based on the amount of reduction in electric power estimated by the electric power reduction amount estimator.

17. An electric power demand prediction method, comprising:
selecting electric power consumption value data included in a certain period out of a consumer's past electric power consumption value data and extracting an outdoor temperature-electric power relation that is a relation between an outdoor temperature and outdoor-temperature-depend electric power varying in accordance with the outdoor temperature out of electric power consumption based on the selected electric power consumption value data;
generating an electric power consumption prediction model for predicting electric power consumption by the consumer in accordance with the outdoor temperature based on the extracted outdoor temperature-electric power relation; and
predicting electric power consumption by the consumer at a time subject to prediction based on the generated electric power consumption prediction model and the outdoor temperature at the time subject to prediction.

18. A consumer profiling system, comprising:
an extractor to select electric power consumption value data included in a certain period out of a consumer's past electric power consumption value data and extract an outdoor temperature-electric power relation that is a relation between an outdoor temperature and outdoor-temperature-depend electric power varying in accordance with the outdoor temperature out of electric power consumption based on the selected electric power consumption value data; and
a profile configurator to set a profile to the consumer based on the outdoor temperature-electric power relation extracted by the extractor.

19. The consumer profiling system according to claim 18, wherein the profile configurator sets a profile of the consumer based on an outdoor temperature at which the consumer starts to use outdoor-temperature-depend electric power out of the outdoor temperature-electric power relation.

20. The consumer profiling system according to claim 18, wherein the profile configurator sets a profile of the consumer based on the outdoor temperature-electric power relation and base electric power as a reference of electric power consumption by the consumer.

21. A consumer profiling method, comprising:
selecting electric power consumption value data included in a certain period out of a consumer's past electric power consumption value data and extracting an outdoor temperature-electric power relation that is a relation between an outdoor temperature and outdoor-temperature-depend electric power varying in accordance with the outdoor temperature out of electric power consumption based on the selected electric power consumption value data; and
setting a profile to the consumer based on the extracted outdoor temperature-electric power relation.
